(19) United States
(12) Patent Application Publication
(10) Pub. No.: US 2026/0254203 A1
(43) Pub. Date: Aug. 27, 2026

(54) LIGHT-EMITTING ELEMENT, MANUFACTURING METHOD AND MANUFACTURING DEVICE FOR SAME, LASER ELEMENT, SEMICONDUCTOR SUBSTRATE, AND ELECTRONIC APPARATUS

(71) Applicant: KYOCERA Corporation, Kyoto-shi, Kyoto (JP)

(72) Inventors: Yoshinobu KAWAGUCHI, Kyoto-shi (JP); Yuki TANIGUCHI, Kyoto-shi (JP); Takeshi KAMIKAWA, Kyoto-shi (JP)

(73) Assignee: KYOCERA Corporation, Kyoto-shi, Kyoto (JP)

(21) Appl. No.: 19/489,661

(22) PCT Filed: Jun. 3, 2024
(86) PCT No.: PCT/JP2024/020185

§ 371 Date: Dec. 3, 2025

(30) Foreign Application Priority Data
Jun. 7, 2023 (JP) 2023-094201

(51) Int. Cl. H01S 5/183; H01S 5/343

(52) U.S. Cl. CPC H01S 5/18361; H01S 5/343

(57) ABSTRACT

A light-emitting element includes a first nitride semiconductor part having a first surface perpendicular to a first crystal orientation, and a second nitride semiconductor part having a second surface perpendicular to a second crystal orientation different from the first crystal orientation and including a light-emitting layer located above the second surface, the second nitride semiconductor part being located above the first surface.

### TECHNICAL FIELD

The present disclosure relates to a light-emitting element and the like.

### BACKGROUND OF INVENTION

Light-emitting elements have been put into practical use in various fields. Depending on the application of the light-emitting element, light having polarized wave (polarization) characteristics is required.

Due to constraints on a material constituting the light-emitting element, an element structure, or the like, light emitted from a light-emitting portion (active layer) in the light-emitting element may have no stable polarization characteristics. For example, when a polarizing filter or the like is provided outside the light-emitting element, the light utilization efficiency is reduced. A technique of emitting light having polarization characteristics from a light-emitting element has been studied (for example, see Non-Patent Document 1).

### CITATION LIST

### Non-Patent Literature

Non-Patent Document 1: Rami T. et. al., “Study and Application of Birefringent Nanoporous GaN in the Polarization Control of Blue Vertical-Cavity Surface-Emitting Lasers”, American Chemical Society (ACS) Photonics April 2021, 8, 1041-1047

### SUMMARY

A light-emitting element in an aspect of the present disclosure includes: a first nitride semiconductor part having a first surface perpendicular to a first crystal orientation; and a second nitride semiconductor part having a second surface perpendicular to a second crystal orientation different from the first crystal orientation and including a light-emitting layer located above the second surface, the second nitride semiconductor part being located above the first surface.

A manufacturing method of a light-emitting element in an aspect of the present disclosure includes: a step of forming a first nitride semiconductor part having a first surface perpendicular to a first crystal orientation; a step of forming a second nitride semiconductor part having a second surface perpendicular to a second crystal orientation different from the first crystal orientation and including a light-emitting layer located above the second surface; and a step of bonding the first surface and the second surface.

### BRIEF DESCRIPTION OF THE DRAWINGS

FIG. 1 is a schematic view for explaining polarization characteristics of light emitted from a light-emitting portion including a nitride semiconductor.

FIG. 2 is a schematic view for explaining a specific example of birefringence characteristics in a multilayer film reflecting mirror.

FIG. 3 is a schematic view illustrating an example of a light-emitting element for explaining the findings of the present disclosure.

FIG. 4 is a schematic view illustrating another example of a light-emitting element for explaining the findings of the present disclosure.

FIG. 5 is a cross-sectional view schematically illustrating a configuration of a light-emitting element in an embodiment of the present disclosure.

FIG. 6 is a flowchart showing an example of a manufacturing method of the light-emitting element in an embodiment of the present disclosure.

FIG. 7 is a block diagram illustrating an example of a manufacturing device of the light-emitting element in an embodiment of the present disclosure.

FIG. 8 is a cross-sectional view of a light-emitting substrate including a plurality of light-emitting elements in a first example, which is taken along an X-direction.

FIG. 9 is a cross-sectional view of the light-emitting substrate including the plurality of light-emitting elements in the first example, which is taken along a Y-direction.

FIG. 10 is a plan view of the light-emitting substrate including the plurality of light-emitting elements in the first example.

FIG. 11 is a partially enlarged cross-sectional view of the light-emitting element in the first example.

FIG. 12 is a flowchart showing an example of a manufacturing method of the light-emitting element in the first example.

FIG. 13 is a step cross-sectional view illustrating an example of a first partial step in the manufacturing method of the light-emitting element in the first example.

FIG. 14 is a step plan view illustrating an example of the first partial step in the manufacturing method of the light-emitting element in the first example.

FIG. 15 is a cross-sectional view illustrating a configuration example of a template substrate.

FIG. 16 is a cross-sectional view illustrating a method for forming a semiconductor part in the first example.

FIG. 17 is a step cross-sectional view illustrating an example of a second partial step in the manufacturing method of the light-emitting element in the first example.

FIG. 18 is a step cross-sectional view illustrating an example of a third partial step in the manufacturing method of the light-emitting element in the first example.

FIG. 19 is a plan view illustrating a singulated light-emitting substrate in a first example.

FIG. 20 is a step plan view illustrating an example of a first partial step in a manufacturing method of a light-emitting element in another configuration example of the first example.

FIG. 21 is a step cross-sectional view illustrating an example of a third partial step in the manufacturing method of the light-emitting element in another configuration example of the first example.

FIG. 22 is a partially enlarged cross-sectional view of another configuration example of the light-emitting element in the first example.

FIG. 23 is a step cross-sectional view illustrating an example of the manufacturing method of the light-emitting element in another configuration example of the first example.

FIG. 24 is a schematic view for explaining the light-emitting element in another configuration example of the first example.

FIG. 25 is a plan view schematically illustrating a configuration of a laser element including a light-emitting element in a second example.

FIG. 26 is a cross-sectional view schematically illustrating the configuration of the laser element including the light-emitting element in the second example.

FIG. 27 is a schematic view illustrating a configuration of an electronic apparatus in a third example.

### DESCRIPTION OF EMBODIMENTS

### Definition and the Like of Terms

Hereinafter, a bias in the distribution of the vibration direction of light is referred to as polarization. Light having a biased distribution of vibration directions may be referred to as polarized light. The polarization direction is a direction in which the magnitude of an electric field vector is maximized among directions orthogonal to the traveling direction of light. In the following drawings, the polarization direction may be indicated by a dashed bidirectional arrow. A polarization ratio can be defined by a ratio of (Is−Ic) to (Is+Ic), where Is is a maximum value of the electric field vector in the polarization direction and Ic is a maximum value of the electric field vector in a direction orthogonal to a traveling direction of light and the polarization direction, and as the polarization ratio increases, a proportion of linearly polarized light increases (a proportion of unpolarized light decreases) and linearly polarized light characteristics become stronger.

In the present specification, a certain substance having birefringence characteristics means that the substance has a property in which an index of refraction varies depending on a polarization direction of incident light to the substance. The substance having the birefringence characteristics has a property in which the reflectance varies depending on the polarization direction of the incident light in relation to the difference in the index of refraction.

In the present specification, the Miller indices of a crystalline structure are indicated by adding a minus sign to the indices, instead of the indication of adding a bar above the indices. In the present specification, forming a film or a layer by crystal growth of a certain substance in a c-axis direction may be referred to as c-plane growth (c-plane film formation), and this also applies to the other axis directions. In the present specification, when a crystal orientation in a crystalline structure of a substance forming a member is expressed for the member mainly made of a single crystal of the substance, the crystal orientation may be simply described as an “a-axis direction of a certain member” for simplification of description.

### Summary of Findings of Present Disclosure

In the following description, in order to facilitate understanding of a light-emitting element of the present disclosure, the summary of findings of the present disclosure is described first.

Specifically, the polarization characteristics of light emitted from a light-emitting portion including a nitride semiconductor are first described, and then the birefringence characteristics of a multilayer film reflecting mirror included in a surface-emitting type optical element are described. Subsequently, an optical element in an aspect of the present disclosure is schematically described.

### Polarization Characteristics of Light Emitted from Nitride Semiconductor

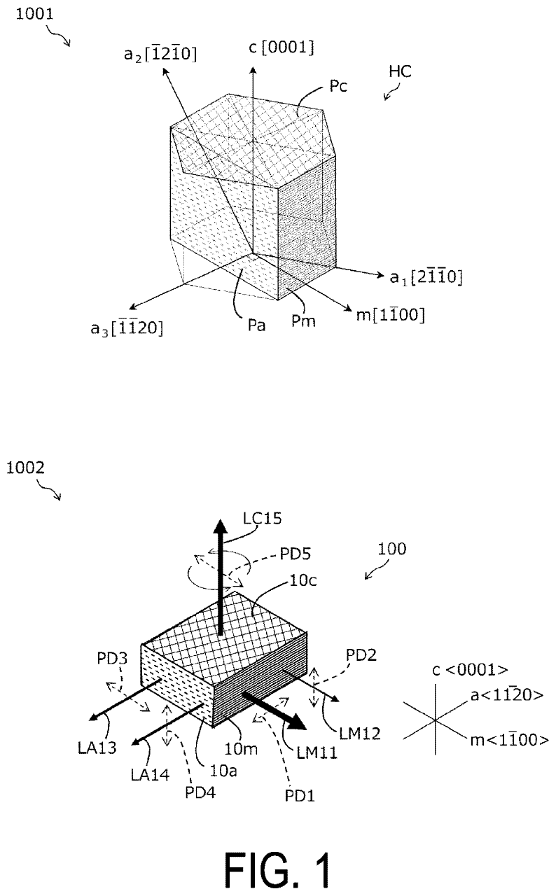

FIG. 1 is a schematic view for explaining polarization characteristics of light emitted from a light-emitting portion including a nitride semiconductor. In the example illustrated in FIG. 1, the nitride semiconductor is gallium nitride (GaN) having a hexagonal crystalline structure. GaN typically has a wurtzite crystalline structure.

The diagram indicated by reference numeral 1001 in FIG. 1 is a schematic view illustrating a hexagonal crystal HC, and in the diagram, coordinate axes of a₁ to a₃ axes and a c-axis are illustrated. The hexagonal crystal HC has a crystal plane Pa (a-plane), a crystal plane Pc (c-plane), and a crystal plane Pm (m-plane) in the crystalline structure, and these crystal planes are orthogonal to the a-axis (for example, a₃ axis), the c-axis, and the m-axis, respectively. The crystal plane Pm corresponds to a cylindrical surface in the hexagonal columnar shape of the hexagonal crystal HC. Various directions are present for the m-axis, and FIG. 1 illustrates the m-axis orthogonal to the a₃ axis and the c-axis. In practice, various equivalent planes are present as the crystal plane Pa, the crystal plane Pc, and the crystal plane Pm. In the diagram indicated by the reference numeral 1001 in FIG. 1, a crystal plane Pa, a crystal plane Pc, and a crystal plane Pm are illustrated with different hatchings.

The diagram indicated by reference numeral 1002 in FIG. 1 is a schematic view illustrating a light-emitting portion 100 in the light-emitting element, and in the diagram, the a-axis, the m-axis, and the c-axis are illustrated. The light-emitting portion 100 may typically be an active layer, and in the diagram indicated by the reference numeral 1002 in FIG. 1, the structure of the light-emitting element other than the light-emitting portion 100 is omitted and schematically illustrated. In the light-emitting portion 100, an upper surface 10c orthogonal to the c-axis corresponds to the crystal plane Pc, a side surface 10a orthogonal to the a-axis corresponds to the crystal plane Pa, and a side surface 10m orthogonal to the m-axis corresponds to the crystal plane Pm. In the diagram indicated by the reference numeral 1002 in FIG. 1, the upper surface 10c, the side surface 10a, and the side surface 10m are illustrated with different hatchings.

In general, light emitted from a semiconductor crystal by radiative recombination may have polarization characteristics corresponding to the orientation of the crystal. For example, when the light-emitting portion 100 is formed of a GaN crystal, the following can be said.

Light emitted from the light-emitting portion 100 has polarization characteristics parallel or perpendicular to the c-axis. Light emitted from the side surface 10m includes a polarized light LM11 having a polarization direction PD1 perpendicular to the c-axis (parallel to the a-axis) and a polarized light LM12 having a polarization direction PD2 parallel to the c-axis (perpendicular to the a-axis). Light emitted from the side 10a includes a polarized light LA13 having a polarization direction PD3 perpendicular to the c-axis (parallel to the m-axis) and a polarized light LA14 having a polarization direction PD4 parallel to the c-axis (perpendicular to the m-axis). Light emitted from the upper surface 10c includes a polarized light LC15 having a polarization direction PD5 perpendicular to the c-axis. Since light is a transverse wave, a wave having a vibration direction parallel to the c-axis (so-called longitudinal wave) is not considered in the light emission from the upper surface 10c. The term “parallel” as used herein does not have to be parallel in the strict sense, allows a deviation of about 5° from the strict parallelism, and is used in the same sense in the following description in the present specification.

Usually, the polarized light LM11 is more dominant than the polarized light LM12 due to the band structure of the GaN crystal, and a high value is reported as the polarization ratio. In general, the light-emitting portion 100 is often formed by c-plane growth from the viewpoint of practical superiority in terms of the manufacturing cost, light emission characteristics, and the like of the light-emitting element. For example, in the case of an edge emitting laser including the light-emitting portion 100, the side surface 10m can be suitably used as a light-emitting surface, and in this case, the laser can be used for applications requiring polarized light.

On the other hand, the polarization direction PD5 of the polarized light LC15 from the upper surface 10c is not determined in a specific direction due to the rotational symmetry of the crystalline structure of GaN. Therefore, when light emitted from the upper surface 10c is used in a surface-emitting type light-emitting element such as a vertical cavity surface emitting laser (hereinafter, referred to as VCSEL) element, stably emitting polarized light having a specific polarization direction is difficult. Since the c-plane is a polar plane and the GaN crystal formed by the c-plane growth is affected by piezoelectric polarization or the like, forming a light-emitting portion by growth of a semipolar plane or a nonpolar plane (for example, m-plane) has been studied, but many practical obstacles are present in terms of cost and mass productivity.

### Birefringence Characteristics of Multilayer Film Reflecting Mirror

In general, a multilayer film reflecting mirror (multilayer film mirror) is used for a surface-emitting type light-emitting element such as a VCSEL element. For example, it has been reported that a distributed Bragg reflector (hereinafter, DBR) in which GaN and aluminum nitride (AlN) are alternately layered by m-plane growth has birefringence characteristics (for example, see the following reference);

[D. M. Schaadt. et. al., “Polarization-dependent beam switch based on an M-plane GaN/AlN distributed Bragg reflector”, APPLIED PHYSICS LETTERS 90, 231117 (2007)].

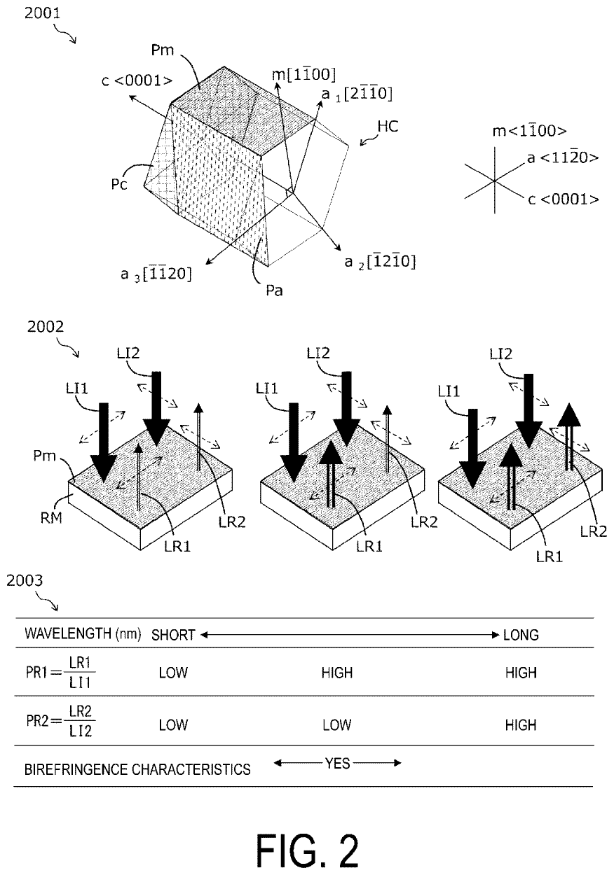

FIG. 2 is a schematic view for explaining a specific example of birefringence characteristics in a multilayer film reflecting mirror. The diagram indicated by reference numeral 2001 in FIG. 2 is a schematic view illustrating a hexagonal crystal HC, and illustrates a state rotated by 90° from the diagram indicated by the reference numeral 1001 in FIG. 1 described above with the a₃ axis direction as a rotation axis direction. In FIG. 2, coordinate axes of an a-axis, an m-axis, and a c-axis corresponding to those in FIG. 1 are illustrated for reference.

The diagram indicated by reference numeral 2002 in FIG. 2 is a schematic view for explaining the birefringence characteristics of a multilayer film reflecting mirror RM when the m-plane is a reflective surface. Reflection light emitted from the crystal plane Pm of the outermost surface in the multilayer film reflecting mirror RM actually has an intensity obtained by superimposing reflection light from each of a plurality of layers layered in the thickness direction of the multilayer film reflecting mirror RM.

The following can be said about the birefringence characteristics when polarized light LI1 and polarized light LI2 are incident perpendicularly to the crystal plane Pm. It is assumed that the polarized light LI1 and the polarized light LI2 are linearly polarized light, the polarized light LI1 has a polarization direction perpendicular to the c-axis (parallel to the a-axis), and the polarized light LI2 has a polarization direction parallel to the c-axis (perpendicular to the a-axis). Reflection light corresponding to the polarized light LI1 is denoted by LR1, and reflection light corresponding to the polarized light LI2 is denoted by LR2. The diagram indicated by the reference numeral 2002 in FIG. 2 illustrates an example in which the wavelengths of the incident light (polarized light LI1 and polarized light LI2) are changed to be longer from the left to the right of the paper surface.

The diagram indicated by reference numeral 2003 in FIG. 2 is a table showing an example of changes in polarized light reflectance when the wavelengths of the polarized light LI1 and the polarized light LI2 to be incident are changed for a certain wavelength band. The ratio of the intensity of the reflection light LR1 to the intensity of the polarized light LI1 is referred to as a polarized light reflectance PR1, and the ratio of the intensity of the reflection light LR2 to the intensity of the polarized light LI2 is referred to as a polarized light reflectance PR2.

In the example illustrated in FIG. 2, when the wavelengths of both the polarized light LI1 and the polarized light LI2 are relatively short, both the polarized light reflectance PR1 and the polarized light reflectance PR2 are relatively low. When the wavelengths of the polarized light LI1 and the polarized light LI2 become longer, the polarized light reflectance PR1 becomes higher than the polarized light reflectance PR2, and the difference between the polarized light reflectance PR1 and the polarized light reflectance PR2 (polarized light reflectance difference) becomes larger. When the wavelengths of the polarized light LI1 and the polarized light LI2 become further longer, both the polarized light reflectance PR1 and the polarized light reflectance PR2 become higher, and the polarized light reflectance difference becomes smaller. In the example illustrated in FIG. 2, the multilayer film reflecting mirror RM has birefringence characteristics in which the polarized light reflectance in the polarization direction perpendicular to the c-axis (parallel to the a-axis) is relatively high in a specific wavelength band.

### For Polarization Control

In general, when a nitride semiconductor such as GaN is used for a light-emitting portion, various demands in terms of manufacturing need to be satisfied in order to achieve high light emission efficiency. For example, reducing the defect density of a GaN-based semiconductor is not easy, and demands for the physical properties (in addition, cost from a practical viewpoint) of a growth substrate are also high. In general, a surface-emitting type light-emitting element such as a VCSEL element has an advantage in manufacturing that a resonator can be monolithically formed on a growth substrate and a chip inspection can be performed on the growth substrate. In the case of manufacturing a VCSEL element “monolithically”, for example, a semiconductor layer (light-emitting layer) is formed on a growth substrate, an upper reflector and a lower reflector are formed by a technique including partial etching and the like of the growth substrate, and an electrode structure is further formed, so that a resonator structure of a large number of VCSELs can be formed on the growth substrate.

Conventionally, the development of a technology for controlling the polarization direction of a surface-emitting type light-emitting element using a nitride semiconductor such as GaN for a light-emitting portion has been limited by a fixed idea assuming monolithic manufacturing and inspection before element separation from the viewpoint of maintaining process advantages and the like. An element structure assuming that a high-quality nitride semiconductor formed by c-plane film formation is used for the light-emitting portion in order to achieve high light emission efficiency has also been limited. For example, options for an underlying structure (growth substrate or the like) of the light-emitting portion are limited.

Therefore, the measures that have been proposed so far for controlling the polarization direction are limited to, for example, interposing a polarization selection layer between two reflectors (for example, multilayer film reflecting mirrors) located apart from each other, generating anisotropy in a part of a constituent member, and the like.

The present inventors have obtained new findings that deviate from the fixed idea as described above while studying the growth technology of the nitride semiconductor and the semiconductor device technology.

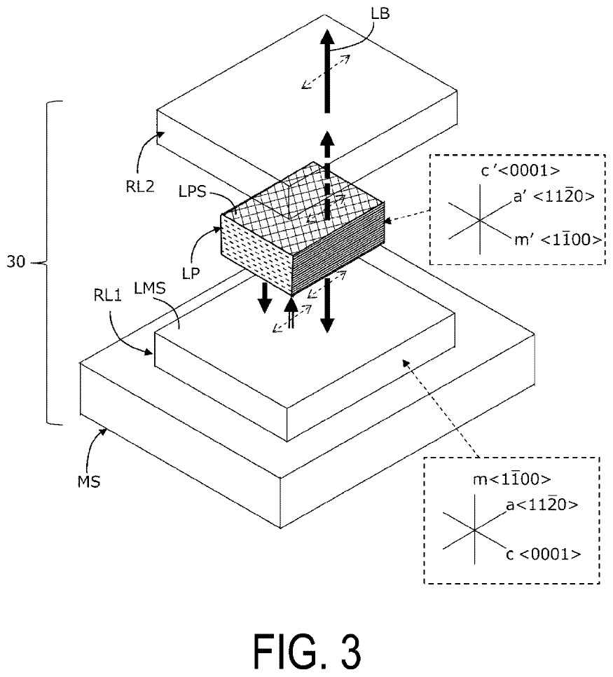

FIG. 3 is a schematic view illustrating an example of a light-emitting element for explaining the findings of the present disclosure. FIG. 3 illustrates an example of a VCSEL element including a GaN crystal in a light-emitting portion. As illustrated in FIG. 3, a light-emitting element 30 in an example has a lower reflective layer RL1 formed on a main substrate (first main substrate) MS, an upper reflective layer RL2 located above the lower reflective layer RL1, and a light-emitting portion LP located between the lower reflective layer RL1 and the upper reflective layer RL2. In FIG. 3, for convenience of description, the lower reflective layer RL1, the light-emitting portion LP, and the upper reflective layer RL2 are illustrated to have a gap among them, but various layers may be interposed among them. In FIG. 3, for the sake of distinction of coordinate axes, coordinate axes related to the lower reflective layer RL1 are defined as a, c, and m axes, and coordinate axes related to the light-emitting portion LP are defined as a′, c′, and m′ axes.

The lower reflective layer RL1 is a DBR formed on the main substrate MS by, for example, m-plane growth, and in this case, a surface LMS of the lower reflective layer RL1 on the light-emitting portion LP side in the layering direction is an m-plane. The lower reflective layer RL1 can be designed to have desired reflectance characteristics corresponding to the emission wavelength of the light-emitting portion LP. A reflectance with respect to unpolarized (nonpolarized) light such as natural light is referred to as a basic reflectance. Usually, the DBR has a wavelength dependence in the basic reflectance. Therefore, the lower reflective layer RL1 is designed to have a high basic reflectance in the range of wavelengths of light emitted from the light-emitting portion LP. In addition, in the light-emitting element 30 of the present disclosure, the lower reflective layer RL1 is designed to have the above-described birefringence characteristics with respect to the emission wavelength of the light-emitting portion LP. In the example illustrated in FIG. 3, the lower reflective layer RL1 has birefringence characteristics in which the polarized light reflectance in the polarization direction parallel to the a-axis is relatively higher than the polarized light reflectance in the other polarization directions.

The light-emitting portion LP is formed on a certain growth substrate by, for example, c-plane growth, and in this case, a surface LPS in the layering direction has a c-plane in the crystalline structure. The light-emitting portion LP may be transferred above the lower reflective layer RL1 while being spaced apart from the growth substrate. A manufacturing method of such a light-emitting element 30 is described in detail below. In the example illustrated in FIG. 3, the a, c, and m axis directions of the lower reflective layer RL1 are parallel to the a′, m′, and c′ axis directions of the light-emitting portion LP, respectively.

In the light-emitting element 30, an upper structure such as the upper reflective layer RL2 may be formed above the light-emitting portion LP, and the upper reflective layer RL2 may be, for example, a DBR. In the example illustrated in FIG. 3, the upper reflective layer RL2 may have no birefringence characteristics.

In the light-emitting element 30 as described above, the lower reflective layer RL1 has the birefringence characteristics described above, and thus polarized light emitted from the light-emitting portion LP in the plane direction (c′-axis direction) and reflected by the lower reflective layer RL1 has a polarization direction in the a-axis direction (a′-axis direction) in the state before laser oscillation. It was found that, in a state where laser oscillation has occurred, a laser beam LB having a specific polarization direction (the a′-axis direction in the example of FIG. 3) can be emitted in the plane direction from the light-emitting element 30. Although details are not yet clear, it is presumable that, in the state before laser oscillation, an oscillation condition is satisfied because polarized light having the polarization direction of the a'-axis direction is likely to be predominantly optically amplified between the lower reflective layer RL1 and the upper reflective layer RL2, whereas no oscillation condition is satisfied because the other polarization components have low reflectances in a reflector having birefringence characteristics (the lower reflective layer RL1 in the above example). Once the polarization component satisfying the oscillation condition oscillates, since injected carriers are preferentially consumed for the oscillation of the polarization component, the oscillation of the other polarization components is further suppressed. As a result, the polarization ratio of polarized light that is most likely to oscillate in the state before the laser oscillation occurs (polarized light having the polarization direction of the a′-axis direction in the above example) may be further increased in the state where the laser oscillation occurs.

For the polarized light reflectance when light having a certain emission wavelength and emitted from the light-emitting portion LP is reflected by the lower reflective layer RL1, the difference between the polarized light reflectance in the polarization direction parallel to the a-axis and the polarized light reflectance in the polarization direction parallel to the c-axis is referred to as a polarized light reflectance difference for convenience of description. It can be said that the larger the polarized light reflectance difference, the stronger the birefringence characteristics. The larger the polarized light reflectance difference in the lower reflective layer RL1 with respect to light having a certain emission wavelength and emitted from the light-emitting portion LP, the higher the polarization ratio of the laser beam LB laser-oscillated by the light-emitting element 30 may be. In the light-emitting element 30, even though the polarized light reflectance difference in the lower reflective layer RL1 is relatively small, the laser oscillation as described above occurs, so that the laser beam LB having a specific polarization direction can be emitted in the plane direction.

Although FIG. 3 illustrates a single light-emitting element, a plurality of light-emitting elements may be two-dimensionally arranged on the main substrate MS. By applying the technology developed by the present inventors, a plurality of high-quality light-emitting portions LP can be transferred above the lower reflective layer RL1 while controlling the crystal orientation of the lower reflective layer RL1 and the crystal orientation of the light-emitting portions LP to have a desired relationship. Thus, a layered body including the lower reflective layer RL1 and the light-emitting portion LP can be two-dimensionally arranged on the main substrate MS, and a subsequent manufacturing process can be performed on the main substrate MS. A chip inspection can be performed on the main substrate MS before a chip division. Therefore, the light-emitting element of the present disclosure can be manufactured without significantly impairing the process advantages of the conventional VCSEL.

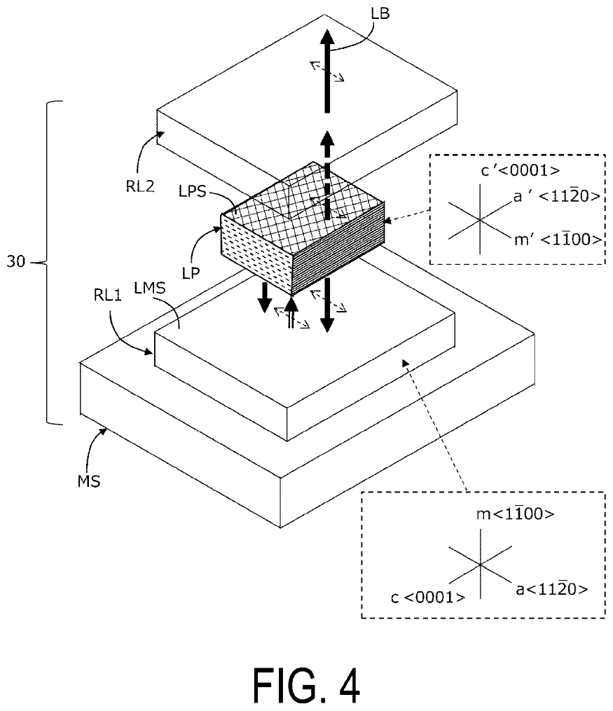

FIG. 4 is a schematic view illustrating another example of a light-emitting element for explaining the findings of the present disclosure. As illustrated in FIG. 4, in the light-emitting element 30 according to another example of the present disclosure, the lower reflective layer RL1 has a crystal orientation rotated by 90° about the m-axis as compared with the example of FIG. 3, and in this case, the laser beam LB having a polarization direction of the m′-axis direction is emitted in the plane direction from the light-emitting element 30.

In the examples illustrated in FIGS. 3 and 4, the polarization direction of the laser beam LB emitted in the plane direction from the light-emitting element 30 corresponds to the direction of the a-axis in the lower reflective layer RL1. In the light-emitting element 30 of another example, the light-emitting portion LP may be further rotated about the c′-axis and located on the lower reflective layer RL1, and in this case, the laser beam LB having a polarization direction between the a′-axis and the m′-axis can be emitted from the light-emitting element 30.

In the light-emitting element 30, the upper reflective layer RL2 may have birefringence characteristics, and the lower reflective layer RL1 may have no birefringence characteristics. In this case, the birefringence characteristics of the upper reflective layer RL2 can control the polarization direction of the laser beam LB emitted in the plane direction from the light-emitting element 30. Both the upper reflective layer RL2 and the lower reflective layer RL1 may have birefringence characteristics, and in this case, the upper reflective layer RL2 and the lower reflective layer RL1 may be arranged so that polarization directions with high polarized light reflectance are aligned.

A DBR formed by the a-plane growth may also have birefringence characteristics. It can be said that the a-plane and the m-plane in the nitride semiconductor crystal are equivalent to each other from some viewpoints. Polarization control can also be performed using the DBR formed by the a-plane growth, as described above with respect to the DBR formed by the m-plane growth. For example, in the light-emitting element 30, the reflective surface of the lower reflective layer RL1 or the upper reflective layer RL2 may be an a-plane, and in this case, the polarization direction of the laser beam LB may be controlled by the birefringence characteristics of the a-plane of the lower reflective layer RL1 or the upper reflective layer RL2.

As described above, according to the light-emitting element in an example of the present disclosure, the polarization of the laser beam LB emitted in the plane direction can be controlled, and the laser beam LB having a required polarization direction can be stably emitted.

The findings of the present disclosure are that, in a light-emitting element including a nitride semiconductor, the polarization characteristics (polarization direction) of light emitted in a plane direction from the light-emitting element can be changed by combining a light-emitting portion and a semiconductor layer having a crystal orientation different from that of the light-emitting portion in a layering direction. This allows the polarization characteristics (polarization direction) of light emitted from the light-emitting element in the plane direction to be controlled relatively easily. In general, various materials are considered for the light-emitting portion, and the multilayer film reflecting mirror may have various birefringence characteristics depending on the structure and the constituent substances of the multilayer film reflecting mirror. Even in such various combinations, a light-emitting element capable of stably emitting polarized light with a controlled polarization direction can be achieved based on the findings of the present disclosure.

Light-emitting Element The light-emitting element in an embodiment of the present disclosure is described below with reference to the drawings. In an embodiment of the present disclosure, an example in which the light-emitting element is a VCSEL element is described; however, the present disclosure is not limited thereto and can be applied to a surface-emitting type light-emitting element such as a resonant cavity light-emitting diode (RCLED) element. In the present embodiment, a current injection type light-emitting element is described as an example; however, the light-emitting element of the present disclosure is not limited thereto and may be of a photoexcitation type. As for the electrode structure of the light-emitting element 30, a known technology can be appropriately selected and used in accordance with the mounting form on a circuit board. As for the excitation structure of the light-emitting element 30, a known technology can also be appropriately selected and used. In the following description, the a, c, and m axes related to the lower reflective layer RL1 and the a′, c′, and m′ axes related to the light-emitting portion LP are appropriately used, and are also appropriately illustrated in the drawings.

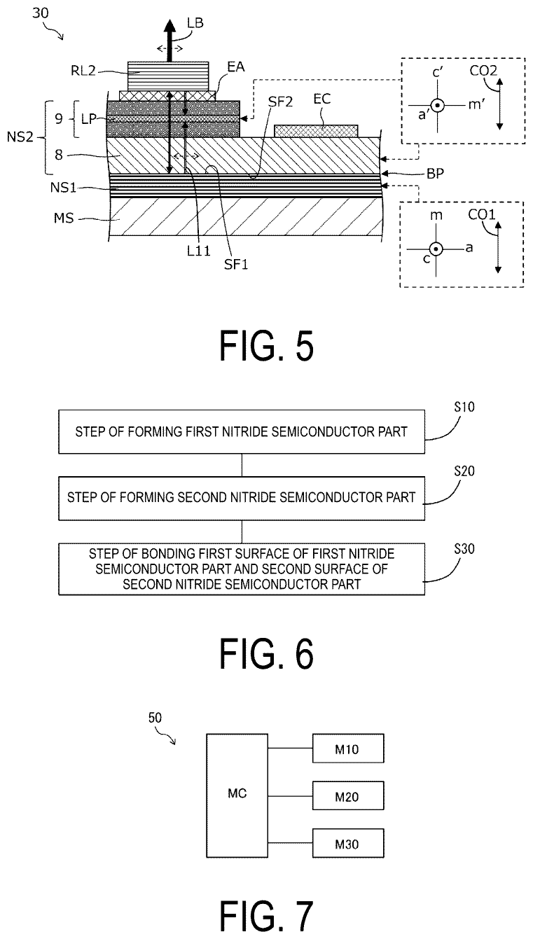

FIG. 5 is a cross-sectional view schematically illustrating the configuration of the light-emitting element in an embodiment of the present disclosure. As illustrated in FIG. 5, the light-emitting element 30 in the present embodiment includes a first nitride semiconductor part NS1 having a first surface SF1 perpendicular to a first crystal orientation CO1, and a second nitride semiconductor part NS2 having a second surface SF2 perpendicular to a second crystal orientation CO2 different from the first crystal orientation CO1 and a light-emitting portion LP located above the second surface SF2, the second nitride semiconductor part NS2 being located above the first surface SF1. The second nitride semiconductor part NS2 includes a base portion 8 and an upper layer portion 9 that is located above the base portion 8 and includes the light-emitting portion LP. The first surface SF1 is a surface of the first nitride semiconductor part NS1 that is located on the second nitride semiconductor part NS2 side, and the second surface SF2 is a surface of the second nitride semiconductor part NS2 that is located on the first nitride semiconductor part NS1 side. The first surface SF1 and the second surface SF2 of the light-emitting element 30 may be bonded to each other. The first nitride semiconductor part NS1 may be a first nitride semiconductor layer, the second nitride semiconductor part NS2 may be a second nitride semiconductor layer, the light-emitting portion LP may be a light-emitting layer, and the base portion 8 may have a layered shape.

The light-emitting element 30 may include a main substrate MS below the first nitride semiconductor part NS1. In the light-emitting element 30, the first nitride semiconductor part NS1 may be a lower reflective layer (corresponding to the lower reflective layer RL1 described above). The light-emitting element 30 may include an upper reflective layer RL2 above the light-emitting portion LP. The light-emitting element 30 may have a bonding portion BP between the first surface SF1 and the second surface SF2. The bonding portion BP is described in detail below. The direction from the main substrate MS toward the first nitride semiconductor part NS1 is defined as an “upward direction”.

In the example illustrated in FIG. 5, the light-emitting element 30 may have an anode EA provided on the upper layer portion 9, and a cathode EC provided on a portion (exposed portion) of the base portion 8 where the upper layer portion 9 is not located. The upper reflective layer RL2, the anode EA, the light-emitting portion LP, the base portion 8, and the first nitride semiconductor part NS1 may overlap one another in plan view. The overlapping of two components in plan view means that at least a part of one component overlaps the other component when viewed (including when perspectively viewed) in the normal direction of the main substrate MS.

Each of the first nitride semiconductor part NS1 and the second nitride semiconductor part NS2 may include a nitride semiconductor as a main material. The nitride semiconductor can be expressed, for example, by AlₓGa_{y}In_{z}N (0≤x≤1; 0≤y≤1; 0≤z≤1; x+y+z=1). Specific examples of the nitride semiconductor may include a GaN-based semiconductor, aluminum nitride (AlN), indium aluminum nitride (InAlN), and indium nitride (InN). The GaN-based semiconductor is a semiconductor containing gallium atoms (Ga) and nitrogen atoms (N). Typical examples of the GaN-based semiconductor include GaN, AlGaN, AlGaInN, and InGaN. The base portion 8 may be of a doped type (for example, an n-type including a donor).

In the light-emitting element 30, each of the first nitride semiconductor part NS1 and the second nitride semiconductor part NS2 may contain a GaN-based semiconductor. Each of the first nitride semiconductor part NS1 and the second nitride semiconductor part NS2 may have the crystalline structure of the hexagonal crystal HC (see FIGS. 1 and 2). The second nitride semiconductor part NS2 may include a c-plane GaN-based semiconductor layer. In the present specification, the c-plane GaN-based semiconductor layer means a GaN-based semiconductor layer formed by c-plane film formation.

In the light-emitting element 30 of the present embodiment, the first surface SF1 may be an m-plane. The first crystal orientation CO1 of the first nitride semiconductor part NS1 having the first surface SF1 being the m-plane is parallel to the m-axis, and the first nitride semiconductor part NS1 has birefringence with respect to light traveling in the direction of the first crystal orientation CO1 as described above. The first nitride semiconductor part NS1 functions as a lower reflective layer, and may be, for example, a DBR having birefringence characteristics. The first nitride semiconductor part NS1 may include a plurality of nitride crystal layers having different indices of refraction. The first nitride semiconductor part NS1 may include an amorphous layer of nitride. The amorphous layer of nitride may have no birefringence characteristics.

In the light-emitting element 30 according to the present embodiment, light generated in the light-emitting portion LP is reflected by the first nitride semiconductor part NS1 and the upper reflective layer RL2 and reciprocates, thereby causing laser oscillation. In the light-emitting element 30, a laser beam is emitted from a side having a relative low reflectance (the upper reflective layer RL2 side). The light-emitting element 30 can emit a relatively weak laser beam also from a side having a relatively high reflectance (the lower reflective layer RL1 side). The upper reflective layer RL2 may be, for example, a DBR including a plurality of dielectric layers. For clarity of description, the following description is given on the assumption that the traveling direction of light between the first nitride semiconductor part NS1 and the upper reflective layer RL2 is a direction orthogonal to the first surface SF1 of the first nitride semiconductor part NS1. Even though a slight deviation is present in the traveling direction of light, the birefringence characteristics do not change significantly. In the light-emitting element 30, the material, the layered structure, and the like of the first nitride semiconductor part NS1 are adjusted (designed) to have required polarized light reflectance characteristics (birefringence characteristics) corresponding to the emission wavelength of the light-emitting portion LP.

In the light-emitting element 30 according to the present embodiment, light (reflection light) L11 traveling from the first surface SF1 of the first nitride semiconductor part NS1 toward the second surface SF2 has a specific polarization direction with respect to the first crystal orientation CO1. For example, in the light-emitting element 30, the first crystal orientation CO1 may be the m-axis direction, and the specific polarization direction of the light (reflection light) L11 from the first surface SF1 may be the a-axis direction of the first nitride semiconductor part NS1. In the light-emitting element 30, the light (reflection light) L11 traveling from the first surface SF1 toward the second surface SF2 may have a polarization ratio exceeding 50% (for example, a polarization ratio of 80% or more).

In the light-emitting element 30 according to the present embodiment, the second surface SF2 of the second nitride semiconductor part NS2 may be a-c-plane. The light-emitting portion LP may be a GaN-based semiconductor layer having a c-plane parallel to the second surface SF2. The light-emitting portion LP may be an active layer. The upper layer portion 9 including the light-emitting portion LP may be formed on the base portion 8 by epitaxial growth. When the second surface SF2 is the-c-plane, the second nitride semiconductor part NS2 may be formed by c-plane growth. The second surface SF2 may be a c-plane. The a′, c′, and m′ axes related to the light-emitting portion LP can be used in common for the entire second nitride semiconductor part NS2. The a, c, and m axes related to the first nitride semiconductor part NS1 may be <11-20>, <0001>, and <1-100> axes of the nitride semiconductor, respectively. The same applies to the a′, c′, and m′ axes related to the light-emitting portion LP (the second nitride semiconductor part NS2).

The findings of the present disclosure are summarized as follows by using the light-emitting element 30 in an embodiment as an example. In general, in a VCSEL that emits a laser beam from the c-plane, a laser beam having a polarization ratio (a proportion of linearly polarized light) is obtained, but since no polarization direction is determined with respect to the crystal orientation, using the VCSEL as a linearly polarized laser is difficult from a design viewpoint. Under such circumstances, it has been found that light emitted from the c-plane of the light-emitting portion LP is light generated by reflection on the m-plane having birefringence characteristics of the first nitride semiconductor part NS1, the light (reflection light) L11 traveling toward the c-plane of the light-emitting portion LP in the direction along the m-axis of the first nitride semiconductor part NS1 has a polarization ratio (larger than 0), and the polarization direction thereof can be a direction (specific direction) determined with respect to the crystal orientation of the first nitride semiconductor part NS1. In the present embodiment, the combination of the c-plane emission and the m-plane reflection can obtain a laser beam that has a high polarization ratio (for example, 80% or more) and a fixed polarization direction (for example, the a-axis direction of the first nitride semiconductor part NS1) and that is easily used as a linearly polarized laser from a design viewpoint.

In the example illustrated in FIG. 5, the layering direction of the second nitride semiconductor part NS2 is parallel to the c′-axis. The second crystal orientation CO2 of the second nitride semiconductor part NS2 is parallel to the c′-axis, and the second nitride semiconductor part NS2 has no birefringence with respect to light traveling in the direction of the second crystal orientation CO2 as described above.

In the example illustrated in FIG. 5, the reflection light L11 from the first surface SF1 has a polarization direction in the a-axis direction (the magnitude of an electric field vector in the a-axis direction is relatively larger than those of electric field vectors in other directions), so that the polarization direction of light emitted from the light-emitting portion LP can be guided to the a-axis direction (the m′-axis direction in the light-emitting portion LP). As a result, the laser beam LB having the polarization direction of the m′-axis direction is emitted from the light-emitting element 30 in the plane direction. Accordingly, in the light-emitting element 30, the polarization of the laser beam LB emitted in the plane direction can be controlled.

Specific examples of the light-emitting element 30 in the present embodiment are described below, but according to the above-described findings, the light-emitting element 30 can have various configuration examples. A brief description is as follows.

In the light-emitting element 30 according to one configuration example, the first surface SF1 may be a semipolar plane or a nonpolar plane (unpolar plane). Since the first surface SF1 is a semipolar plane or a nonpolar plane and the first nitride semiconductor part NS1 has birefringence characteristics, the reflection light L11 from the first surface SF1 can have a specific polarization direction. For example, when the first nitride semiconductor part NS1 has the crystalline structure of the hexagonal crystal HC, the semipolar plane is a plane having a plane orientation oblique to the c-axis of the hexagonal crystal HC. The semipolar plane actually includes various planes, and examples thereof include a (11-22) plane and a (1-101) plane. The nonpolar plane is a plane having a plane orientation perpendicular to the c-plane of the hexagonal crystal HC, and is, for example, an m-plane or an a-plane.

In the light-emitting element 30 according to one configuration example, the first surface SF1 may be an m-plane or an a-plane. For example, when the first crystal orientation CO1 is the a-axis direction (the first surface SF1 is the a-plane), the specific polarization direction of the reflection light L11 from the first surface SF1 may be the m-axis direction of the first nitride semiconductor part NS1. The first nitride semiconductor part NS1 and the second nitride semiconductor part NS2 may have a crystalline structure different from that of the hexagonal crystal HC. The first nitride semiconductor part NS1 and the second nitride semiconductor part NS2 may be, for example, cubic crystals, a plane orientation having birefringence characteristics may be used as the first surface SF1, and the first surface SF1 may be a (111) plane of the cubic crystal. In the light-emitting element 30 according to one configuration example, the second surface SF2 may be a polar surface. The second surface SF2 is not necessarily limited to the c-plane or the-c-plane. The reflection light L11 from the first surface SF1 has a specific polarization direction, and the second nitride semiconductor part NS2 has no birefringence with respect to light traveling in the direction of the second crystal orientation CO2, so that the laser beam LB having a specific polarization direction is emitted from the light-emitting element 30 in the plane direction.

In the light-emitting element 30 according to one configuration example, the first surface SF1 and the second surface SF2 may be directly bonded to each other at the bonding portion BP. The technique of direct bonding is not particularly limited, and may be surface activated bonding, or bonding may be performed by heating and pressurization. In the case of direct bonding at the bonding portion BP, the materials of the base portion 8 and the first nitride semiconductor part NS1 may be selected in consideration of a lattice mismatch and the like. Usually, an amorphous layer may be formed at an interface between the first nitride semiconductor part NS1 and the base portion 8 by the direct bonding. The light-emitting element 30 may include a transition layer between the first surface SF1 and the second surface SF2. The transition layer is not particularly limited, and examples thereof include an amorphous layer, an oxide layer, a layer containing defects (dislocation and the like), and a composite layer including two or more layers selected from the group consisting of these layers. The amorphous layer may contain oxygen. The bonding portion BP may include the transition layer.

The light-emitting element 30 may include a medium layer such as a transparent adhesive layer between the first nitride semiconductor part NS1 and the second nitride semiconductor part NS2 as long as light can travel back and forth between the lower reflective layer RL1 and the upper reflective layer RL2 to cause laser oscillation. The first surface SF1 and the second surface SF2 may be bonded to each other via a light-transmissive bonding material.

### Manufacturing Method of light-emitting Element

FIG. 6 is a flowchart showing an example of the manufacturing method of the light-emitting element in an embodiment of the present disclosure. As illustrated in FIG. 6, the manufacturing method of the light-emitting element in an embodiment includes step S10 of forming the first nitride semiconductor part NS1 having the first surface SF1 perpendicular to the first crystal orientation CO1, step S20 of forming the second nitride semiconductor part NS2 having the second surface SF2 perpendicular to the second crystal orientation CO2 different from the first crystal orientation CO1 and the light-emitting portion LP located above the second surface SF2, and step S30 of bonding the first surface SF1 and the second surface SF2.

In the step of forming the first nitride semiconductor part NS1, for example, the first nitride semiconductor part NS1 can be crystal-grown on the main substrate MS. The second nitride semiconductor part NS2 can be formed using, for example, an epitaxial lateral overgrowth (ELO) method. The second nitride semiconductor part NS2 may be formed using another technique as long as the technique can implement the light-emitting portion LP with a low defect. In the manufacturing method of the light-emitting element according to the embodiment, for example, the second nitride semiconductor part NS2 crystal-grown on a template substrate including a seed region and a growth suppression region may be peeled off, and the second surface SF2 of the peeled second nitride semiconductor part NS2 may be directly bonded to the first surface SF1 of the first nitride semiconductor part NS1.

In the manufacturing method of the light-emitting element according to an example, the first surface SF1 and the second surface SF2 may be bonded to each other by heating and/or pressurization. In the manufacturing method of the light-emitting element according to an example, the first surface SF1 and the second surface SF2 may be bonded to each other via a light-transmissive bonding material.

### Manufacturing Device

FIG. 7 is a block diagram illustrating an example of a manufacturing device of the light-emitting element in an embodiment of the present disclosure. A manufacturing device 50 of the light-emitting element illustrated in FIG. 7 includes a device M10 for performing step S10 illustrated in FIG. 6, a device M20 for performing step S20 illustrated in FIG. 6, a device M30 for performing step S30 illustrated in FIG. 6, a control device MC for controlling the devices M10, M20, and M30.

The device M10 and the device M20 may include an MOCVD device, and the control device MC may include a processor and a memory. The control device MC may be configured to, for example, control the device M10, the device M20, and the device M30 by executing a program stored in a built-in memory, a communicable communication device, or an accessible network, and the present embodiment also includes the program and a recording medium storing the program therein.

### First Example

In the first example, a light-emitting substrate 40 having a plurality of light-emitting elements 30 is described as an example. In the first example, the light-emitting element 30 is a VCSEL element. One or more light-emitting elements 30 are cut out from the light-emitting substrate 40, and a single light-emitting element 30 or a plurality of light-emitting elements 30 can be mounted on a submount, a circuit board, or the like.

### Overall Configuration

Details of each part of the light-emitting element in the first example are described in more detail below together with the description of an example of the manufacturing method of the light-emitting element, but the overall configuration is schematically described as follows.

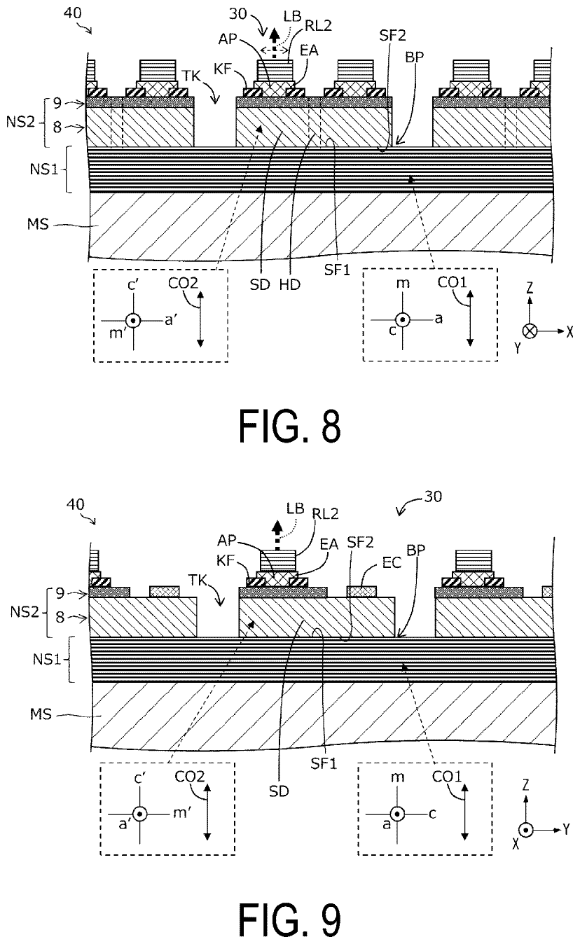

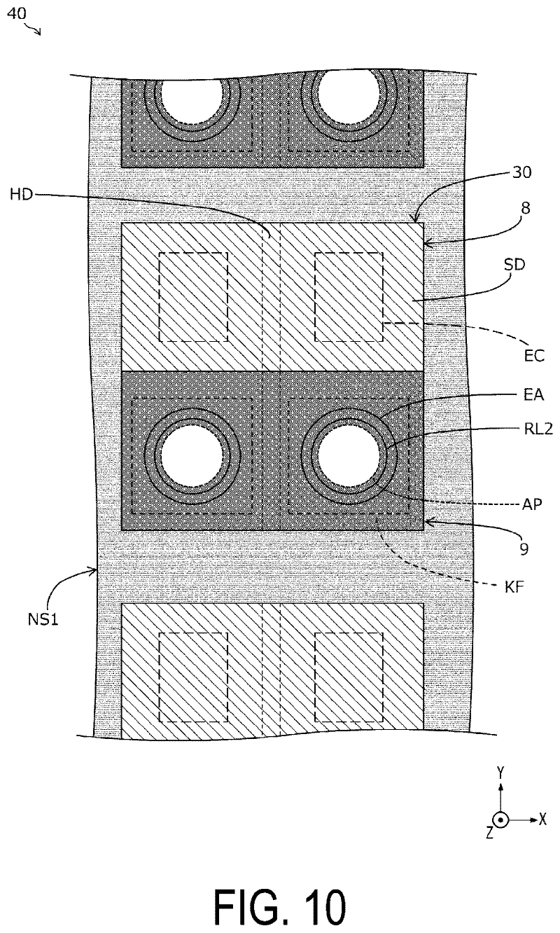

FIG. 8 is a cross-sectional view of a light-emitting substrate including a plurality of light-emitting elements in the first example, which is taken along an X-direction. FIG. 9 is a cross-sectional view of the light-emitting substrate including the plurality of light-emitting elements in the first example, which is taken along a Y-direction. FIG. 10 is a plan view of the light-emitting substrate including the plurality of light-emitting elements in the first example. As illustrated in FIGS. 8, 9, and 10, the light-emitting element 30 in the first example includes a main substrate MS, a first nitride semiconductor part NS1 located on the main substrate MS, a second nitride semiconductor part NS2 located on the first nitride semiconductor part NS1, an insulating film KF and an anode EA located on the second nitride semiconductor part NS2, an upper reflective layer RL2 located on the anode EA, and a cathode EC located on a base portion 8.

The second nitride semiconductor part NS2 includes the base portion 8 and an upper layer portion 9. The base portion 8 and the upper layer portion 9 may each include a nitride semiconductor (for example, a GaN-based semiconductor). In the first example, the X direction is the a-axis direction of the first nitride semiconductor part NS1, the a′-axis direction of the second nitride semiconductor part NS2, and the <11-20> direction of the nitride semiconductor. The Y direction is the c-axis direction of the first nitride semiconductor part NS1 and the m′-axis direction of the second nitride semiconductor part NS2, that is, the <1-100> direction of the nitride semiconductor forming the second nitride semiconductor part NS2. A Z direction is the m-axis direction of the first nitride semiconductor part NS1 and the c′-axis direction of the second nitride semiconductor part NS2, that is, the <0001> direction of the nitride semiconductor forming the second nitride semiconductor part NS2.

In the first example, the base portion 8 includes a first portion HD and a second portion SD (low-defect portion) having a threading dislocation density of ⅕ or less of that of the first portion HD. The threading dislocation density of the second portion SD may be 5×10⁶/cm² or less. The second nitride semiconductor part NS2 including such a base portion 8 can be formed by, for example, an ELO method (to be described below). The second portion SD overlaps the upper layer portion 9 in plan view. A portion of the upper layer portion 9 that overlaps the second portion SD in plan view is a low dislocation portion taking over the low dislocation characteristic (low defect characteristic) of the base portion 8. The first nitride semiconductor part NS1 functioning as a lower reflective layer and the upper reflective layer RL2 can be configured to overlap the second portion SD in plan view.

In the light-emitting element 30, light generated in the light-emitting portion LP (see FIG. 5) of the upper layer portion 9 by an electrical current between the anode EA and the cathode EC causes laser oscillation by stimulated emission and feedback action between the first nitride semiconductor part NS1 and the upper reflective layer RL2. In the light-emitting element 30, the first surface SF1 is an m-plane, and the first nitride semiconductor part NS1 has birefringence with respect to light traveling in the direction of a first crystal orientation CO1. The first nitride semiconductor part NS1 has a relatively higher polarized light reflectance in the a-axis direction than in other directions in the first surface SF1. In the light-emitting element 30, the second surface SF2 is a c-plane, and the second nitride semiconductor part NS2 has no birefringence with respect to light traveling in the direction of a second crystal orientation CO2. Thus, the light-emitting element 30 can emit a laser beam LB having a specific polarization direction in the plane direction when an electrical current is injected between the anode EA and the cathode EC. In the first example, the specific polarization direction is the a′-axis direction of the second nitride semiconductor part NS2 (the a-axis direction of the first nitride semiconductor part NS1).

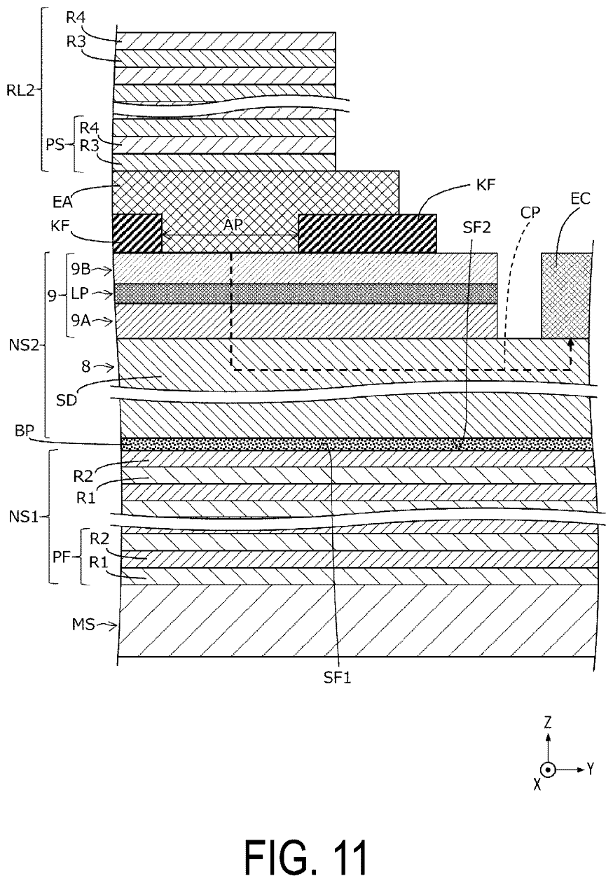

FIG. 11 is a partially enlarged view of the light-emitting element in the first example. As illustrated in FIG. 11, the upper layer portion 9 includes an n-type semiconductor layer 9A as a first-type semiconductor layer, a light-emitting portion LP, and a p-type semiconductor layer 9B as a second-type semiconductor layer in this order from a lower layer side. The light-emitting portion LP is an active layer, has a multi-quantum well (MQW) structure, and includes, for example, at least one of InGaN and GaN. The n-type semiconductor layer 9A is, for example, an n-type AlGaN layer. The p-type semiconductor layer 9B is, for example, a p-type GaN layer. The anode EA is provided to be in contact with the p-type semiconductor layer 9B.

The light-emitting element 30 includes the insulating film KF located on the upper layer portion 9, and the insulating film KF includes an aperture portion AP overlapping the upper reflective layer RL2, the anode EA, the light-emitting portion LP, the second portion SD, and the first nitride semiconductor part NS1 in plan view. The anode EA is a transparent electrode located between the upper layer portion 9 and the upper reflective layer RL2, and is in contact with an upper surface of the insulating film KF. For the insulating film KF, SiOx, SiNx, AlOx, or the like can be used.

In the aperture portion AP, the anode EA and the upper layer portion 9 are in contact with each other. Specifically, the p-type semiconductor layer 9B exposed from the aperture portion AP is in contact with a central portion of the anode EA. The aperture portion AP is a current constriction portion formed by, for example, circularly penetrating the insulating film KF, and constricts a current path CP between the anode EA and the cathode EC on the anode EA side, thereby enhancing the light emission efficiency. In the first example, the current path CP from the anode EA in the aperture portion AP to the cathode EC through the upper layer portion 9 and the base portion 8 is formed in the low-defect portion of the base portion 8 and the upper layer portion 9. This enhances the light emission efficiency in the light-emitting portion LP, while suppressing heat generation in the base portion 8 and the upper layer portion 9.

In the first example, the first nitride semiconductor part NS1 can be an epitaxial DBR including a nitride semiconductor and formed by m-plane growth on the main substrate MS. The first nitride semiconductor part NS1 has a plurality of pairs PF each including a first refractive portion R1 and a second refractive portion R2 having a larger index of refraction than the first refractive portion R1. The second refractive portion R2 may contain a GaN-based semiconductor, and the first refractive portion R1 may contain a refractive material (for example, a nitride semiconductor) having a smaller index of refraction than the GaN-based semiconductor of the second refractive portion R2. The first nitride semiconductor part NS1 formed as the epitaxial DBR including a nitride semiconductor increases the light reflectance of the first nitride semiconductor part NS1.

The first nitride semiconductor part NS1 may have a structure in which the first refractive portion R1 and the second refractive portion R2 are repeatedly layered in this order on the main substrate MS from the viewpoint of increasing the reflectance. In the first example, the first surface SF1 of the first nitride semiconductor part NS1 corresponds to an upper surface of the second refractive portion R2 and is the m-plane of the crystalline structure of the nitride semiconductor. The second surface SF2 of the second nitride semiconductor part NS2 corresponds to a lower surface of the base portion 8 and is the-c-plane of the crystalline structure of the nitride semiconductor.

The specific layered structure of the first nitride semiconductor part NS1 is not particularly limited, and for example, a known epitaxial DBR structure can be appropriately applied. The thickness of the first nitride semiconductor part NS1 may be modulated, and the order of layering the first refractive portion R1 and the second refractive portion R2 may be appropriately set. The first refractive portion R1 and the second refractive portion R2 can be layered in various combinations. For example, since the reflectance is not affected when an optical thickness is set to ½λ the first refractive portion side R1 having an optical thickness of ½λ may be disposed as the uppermost layer of the first nitride semiconductor part NS1 in the first nitride semiconductor part NS1, and in this case, the first surface side SF1 corresponds to an upper surface of the first refractive portion side R1. The second refractive portion R2 having an optical thickness of ½λ may be disposed as the lowermost layer of the first nitride semiconductor part NS1 (layer located on the surface of the main substrate MS).

In the first example, the bonding portion BP is provided between the first nitride semiconductor part NS1 and the base portion 8. Specifically, the bonding portion BP is a transition layer (a layer generated as a by-product of bonding) formed by directly bonding the first nitride semiconductor part NS1 and the second nitride semiconductor part NS2, and is, for example, an amorphous layer. In the light-emitting element 30, the first surface SF1 and the second surface SF2 may be formed of the same nitride semiconductor. The first surface SF1 may be an interface between the first nitride semiconductor part NS1 and the bonding portion BP, and the second surface SF2 may be an interface between the base portion 8 and the bonding portion BP. The bonding portion BP may be a crystal layer including defects (dislocations or the like) instead of an amorphous layer.

In the light-emitting element 30, the root mean square surface roughness (RMS) of each of the first surface SF1 and the second surface SF2 is 0.5 nm or less. This can facilitate direct bonding between the first nitride semiconductor part NS1 and the second nitride semiconductor part NS2. The RMS of each of the first surface SF1 and the second surface SF2 can be measured in a state before the direct bonding is performed. When the first nitride semiconductor part NS1 and the second nitride semiconductor part NS2 are directly bonded, the RMS of each of the first surface SF1 and the second surface SF2 in the state before the direct bonding is performed can be indirectly specified to be 0.5 nm or less.

The materials and the crystal orientations of the first nitride semiconductor part NS1 and the second nitride semiconductor part NS2 can be adjusted to reduce a lattice mismatch between the first surface SF1 of the first nitride semiconductor part NS1 and the second surface SF2 of the second nitride semiconductor part NS2. In this case, the first nitride semiconductor part NS1 and the second nitride semiconductor part NS2 may be directly bonded seamlessly. The bonding portion BP may be an interface between the first surface SF1 and the second surface SF2 instead of an amorphous layer.

The upper reflective layer RL2 can be located on the anode EA and can be a dielectric DBR including a dielectric body. For example, the upper reflective layer RL2 has a plurality of pairs PS each including a third refractive portion R3 and a fourth refractive portion R4 having a larger index of refraction than the third refractive portion R3, and each of the third refractive portion R3 and the fourth refractive portion R4 includes a dielectric material. A lower surface of the upper reflective layer RL2 may be included in the third refractive portion R3, and an upper surface of the upper reflective layer RL2 may be included in the fourth refractive portion R4. The third refractive portion R3 may have a smaller index of refraction than the anode EA. This can increase the light reflectance of the upper reflective layer RL2. The upper reflective layer RL2 provided in an island shape on the anode EA increases heat dissipation.

As illustrated in FIGS. 8 and 9, the light-emitting substrate 40 of the first example may have a gap TK between the plurality of light-emitting elements 30. The side surfaces of the base portion 8 and the upper layer portion 9 may each be an a-plane or an m-plane of the GaN-based semiconductor.

### Manufacturing Method

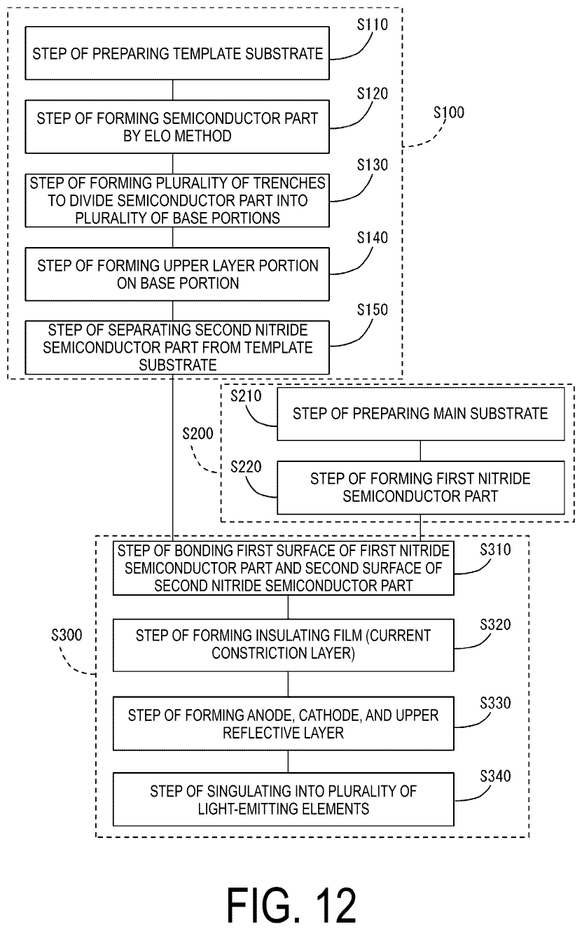

FIG. 12 is a flowchart showing an example of the manufacturing method of the light-emitting element in the first example. As illustrated in FIG. 12, the example of the manufacturing method of the light-emitting element includes a first partial step S100, a second partial step S200, and a third partial step S300. The first partial step S100, the second partial step S200, and the third partial step S300 are described below in order.

### First partial Step

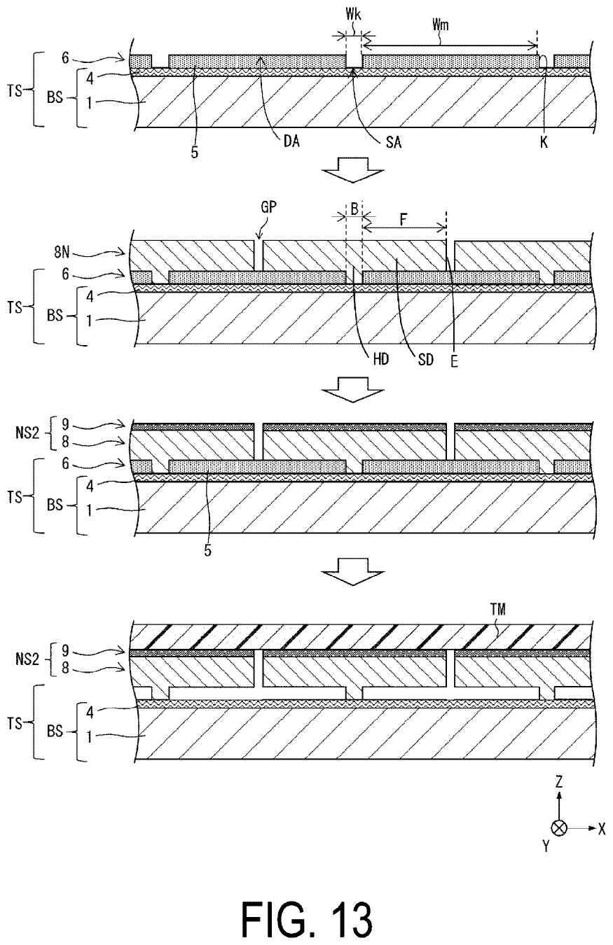

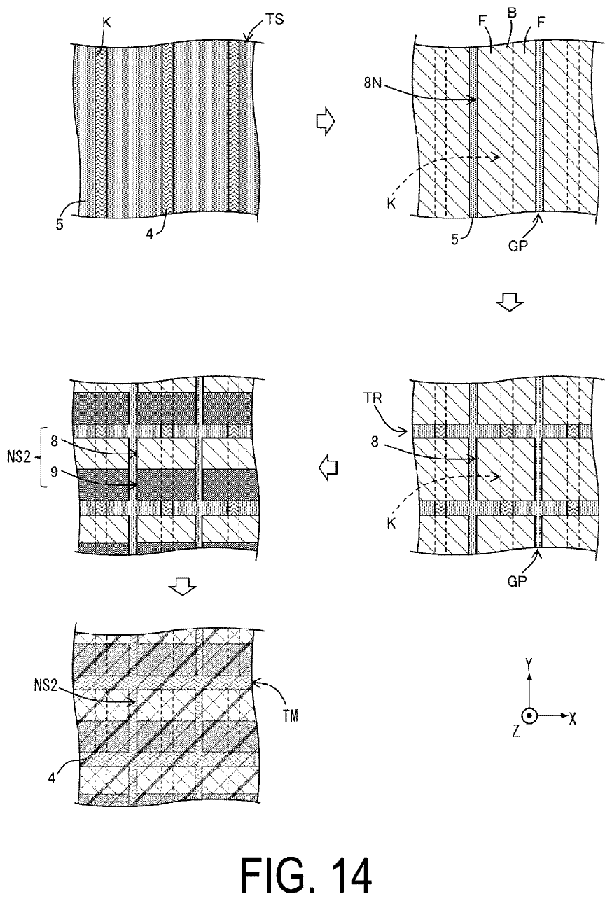

FIG. 13 is a step cross-sectional view illustrating an example of the first partial step in the manufacturing method of the light-emitting element in the first example. FIG. 14 is a step plan view illustrating an example of the first partial step in the manufacturing method of the light-emitting element in the first example. As illustrated in FIGS. 12 to 14, the first partial step S100 includes step S110 of preparing a template substrate TS, step S120 of forming a semiconductor part 8N by an ELO method, step S130 of forming a plurality of trenches TR to divide the semiconductor part 8N into a plurality of base portions 8, step S140 of forming the upper layer portion 9 on the base portion 8, and step S150 of separating the second nitride semiconductor part NS2 from the template substrate TS. In the first example, the upper layer portion 9 is formed above the template substrate TS by c-plane growth. In another example, the upper layer portion 9 may be formed on the semiconductor part 8N, and then the semiconductor part 8N and the upper layer portion 9 may be divided, thereby forming an island-shaped portion (corresponding to the second nitride semiconductor part NS2 described above) including the base portion 8 and the upper layer portion 9 on the template substrate TS.

### Template Substrate

The template substrate TS includes a seed region SA and a growth suppression region DA arranged in a first direction (X direction). The template substrate TS may include, for example, a main substrate (second main substrate) 1, an underlying portion 4, and a mask pattern 6. The mask pattern 6 may include a mask portion 5 that functions as the growth suppression region DA and an opening portion K corresponding to the seed region SA. Specifically, a surface (upper surface) of the mask portion 5 may be the growth suppression region DA. The main substrate 1 and an underlying portion 4 may be collectively referred to as a base substrate BS. The template substrate TS can also be referred to as a growth substrate.

A different substrate having a lattice constant different from that of the semiconductor part 8N containing, for example, the GaN-based semiconductor can be used for the main substrate 1. Examples of the different substrate include a single-crystal silicon (Si) substrate, a sapphire (Al₂O₃) substrate, a silicon carbide (SiC) substrate, and an aluminum nitride (AIN) substrate. A plane orientation of the main substrate 1 is, for example, the (111) plane of the silicon substrate, the (0001) plane of the sapphire substrate, or the 6H-SiC (0001) plane of the SiC substrate. These are illustrative, and in the first example, any substrate and any plane orientation may be used as long as the substrate and the plane orientation can form the semiconductor part 8N by using the ELO method and can grow the upper layer portion 9 above the semiconductor part 8N (or the base portion 8 obtained by dividing the semiconductor part 8N) by the c-plane growth.

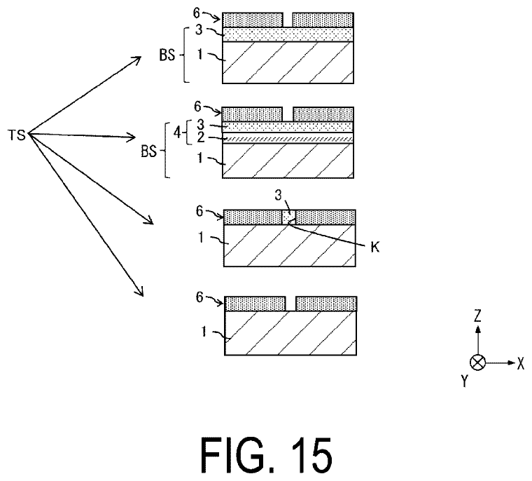

FIG. 15 is a cross-sectional view illustrating a configuration example of the template substrate. As illustrated in FIG. 15, the template substrate TS may have a configuration in which a seed portion 3 and the mask pattern 6 are formed in this order on the main substrate 1, and in this case, the underlying portion 4 may be the seed portion 3. The template substrate TS may also have a configuration in which a plurality of underlying portions 4 (including a buffer portion 2 and the seed portion 3) and the mask pattern 6 are formed in this order on the main substrate 1. The seed portion 3 may be locally (for example, in a stripe shape) formed to overlap the opening portion K of the mask pattern 6 in plan view. The template substrate TS may have a configuration in which the mask pattern 6 is formed on the main substrate 1 (for example, a SiC bulk crystal substrate).

The seed portion 3 is a growth starting point of the semiconductor part 8N, and may overlap the opening portion K in plan view and have a shape with a second direction (Y direction) as a longitudinal direction. For the seed portion 3, an underlying material such as a GaN-based semiconductor, aluminum nitride (AlN), silicon carbide (SiC), AlScN, and graphene may be used.

For example, when a silicon substrate is used for the main substrate 1 and a GaN-based semiconductor is used for the seed portion 3, the buffer portion 2 including at least one of an AIN layer and a silicon carbide (SiC) layer may be provided to reduce the possibility of these (the main substrate and the seed portion) melting together. Use of the main substrate 1 unlikely to melt with the seed portion 3 enables a configuration not provided with the buffer portion 2. Use of the seed portion 3 having low reactivity with the main substrate 1 also enables a configuration not provided with the buffer portion 2. The buffer portion 2 may include a strain relaxation layer. Examples of the strain relaxation layer include an AlGaN superlattice structure and a graded structure in which the Al composition of AlGaN is changed stepwise.

At least one of the buffer portion 2 (for example, aluminum nitride) and the seed portion 3 (for example, the GaN-based semiconductor) can be formed using a sputtering device (pulse sputter deposition (PSD), pulse laser deposition (PLD), or the like). Film formation using the sputtering device can streamline the manufacturing process.

The mask pattern 6 is formed on the main substrate 1 or the base substrate BS by using a material that suppresses longitudinal growth (growth in the c-axis direction) of the nitride semiconductor, and achieves lateral growth (for example, growth in the a-axis direction) of the nitride semiconductor. Examples of the material of the mask portion 5 of the mask pattern 6 include silicon nitride, silicon carbide, silicon carbonitride, diamond-like carbon, silicon oxide, and silicon oxynitride. Examples of the material of the mask portion 5 include titanium nitride, molybdenum nitride, tungsten nitride, and tantalum carbide, which contain no silicon, and further include high melting point metals (molybdenum, tungsten, platinum, and the like). The mask portion 5 may be a single layer film made of one of these materials, or a multi-layer film obtained by combining a plurality of these materials. The thickness of the mask portion 5 may be approximately 100 nm to 4 μm, for example. A width Wm (size in the first direction) of the mask portion 5 may be, for example, 10 μm to 200 μm.

The opening portion K of the mask pattern 6 may have a longitudinal shape with the first direction (X direction) as a width direction and the second direction (Y direction) as a longitudinal direction. In the mask pattern 6, a plurality of opening portions K may be arranged side by side in the first direction. The opening portion K may have a tapered shape (shape that narrows downward). A width Wk (size in the first direction) of the opening portion K may be, for example, approximately 0.1 μm to 20 μm. The width Wk of the opening portion K may be smaller than the width Wm of the mask portion 5.

### Film Formation of Semiconductor Part

The semiconductor part 8N is formed on the template substrate TS by using an ELO method. In the first example, an ELO film of the semiconductor part 8N is formed on the template substrate TS by using a metal-organic chemical vapor deposition (MOCVD) device with the semiconductor part 8N as a GaN layer so that an upper surface of the ELO film is a c plane. The following can be adopted as examples of the ELO film formation conditions: substrate temperature: 1120° C., growth pressure: 50 kPa, trimethylgallium (TMG): 22 sccm, NH₃: 15 slm, and V/III=6000 (ratio of group V raw material supply amount to group III raw material supply amount).

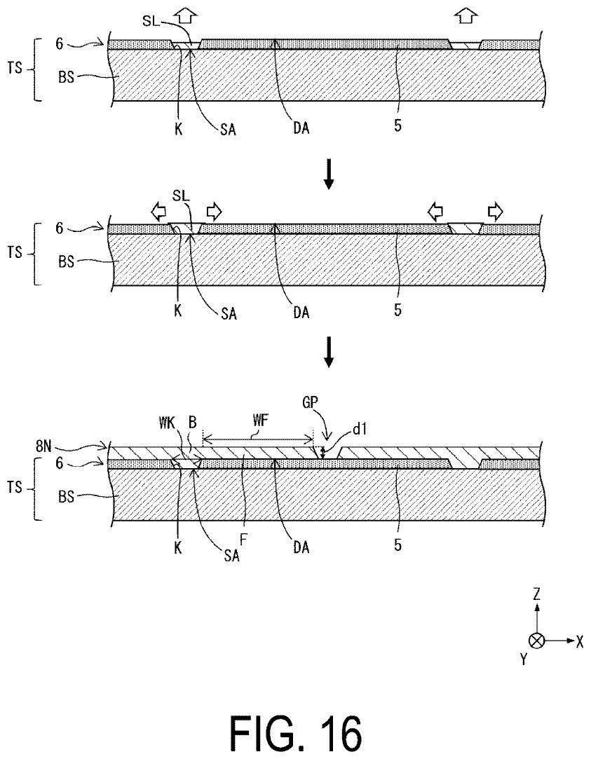

FIG. 16 is a cross-sectional view illustrating an example of the method for forming the semiconductor part in the first example. FIG. 16 illustrates an example in which the mask portion 5 in the mask pattern 6 has a tapered opening portion K. As illustrated in FIG. 16, an initial growth portion SL may be formed on the seed region SA exposed from the opening portion K, and then the semiconductor part 8N may be laterally grown from the initial growth portion SL. The initial growth portion SL serves as a starting point of the lateral growth of the semiconductor part 8N. The semiconductor part 8N can be controlled to grow in the c-axis direction or in the a-axis direction (first direction (X direction)) of the nitride semiconductor by appropriately controlling an ELO film formation condition.

For example, the film formation of the initial growth portion SL may be stopped at a timing immediately before an edge of the initial growth portion SL rides on the upper surface of the mask portion 5 (a stage of being in contact with the upper end of a side surface of the mask portion 5) or immediately after the edge of the initial growth portion SL rides on the upper surface of the mask portion 5 (that is, at this timing, the ELO film formation condition may be switched from a c-axis direction film formation condition to an a-axis direction film formation condition). By making the initial growth portion SL laterally grow from a state of being slightly protruding from the mask portion 5, the growth of the semiconductor part 8N in the c-axis direction (thickness direction) can be suppressed, the semiconductor part 8N can be laterally grown at high speed and with high crystallinity, and further the consumption of raw materials is reduced. This makes it possible to form the thin, wide, and low-defect semiconductor part 8N (a crystal body of a nitride semiconductor such as GaN) at low cost. The initial growth portion SL can be formed to have a thickness of, for example, 30 nm to 1000 nm, 50 nm to 400 nm, or 70 nm to 350 nm.

The film-forming temperature of the semiconductor part 8N (ELO semiconductor part) may be higher than 1200° C. or may be equal to or less than 1150° C. From the viewpoint of reducing mutual reactions, the semiconductor part 8N can be formed at a low temperature below 1000° C. In such low-temperature film formation, with trimethylgallium (TMG) as a gallium raw material, the raw material is not sufficiently decomposed, and gallium atoms and carbon atoms are simultaneously taken into the semiconductor part 8N in larger quantities than usual. The carbon taken into the semiconductor part 8N reduces a reaction with the mask portion 5 and reduces adhesion and the like between the mask portion 5 and the semiconductor part 8N. Therefore, in the low-temperature film formation of the semiconductor part 8N, the supply amount of ammonia may be reduced, and the film formation may be performed at a low V/III (<1000). Thus, carbon elements in the raw material or a chamber atmosphere can be taken into the semiconductor part 8N to reduce a reaction between the semiconductor part 8N and the mask portion 5.

The semiconductor parts 8N laterally grown in opposite directions from two adjacent opening portions K are not in contact with (do not meet) each other on the mask portion 5, but have a gap (interval) GP, thereby making it possible to reduce an internal stress in the semiconductor parts 8N. This can reduce cracks and defects (dislocations) that may be produced in the semiconductor part 8N. The width of the gap GP (size in the first direction X1) can be, for example, 5 μm or less, 3 μm or less, or 2 μm or less.

In the semiconductor part 8N, a base B located on the initial growth portion SL serves as a dislocation inheriting portion (the first portion HD described above) in which a large number of threading dislocations occur, and a wing F located on the mask portion 5 serves as a low-defect portion (the second portion SD described above) in which a threading dislocation density is ⅕ or less compared to the dislocation inheriting portion. The wing F includes an edge E located above the growth suppression region DA. The threading dislocation is a dislocation (defect) extending in the semiconductor part 8N in the c-axis direction (<0001> direction) thereof. The threading dislocation density can be obtained by, for example, performing cathode luminescence (CL) measurement on the surface of the semiconductor part 8N and counting the number of black spots in a CL measurement image. The threading dislocation density of the wing F can be set to, for example, 5×10⁶[spots/cm² ] or less.

The basal plane dislocation density of the base B may be 5×10⁸/cm² or less. The basal plane dislocation may be a dislocation extending in an in-plane direction of the c-plane of the semiconductor part 8N. The basal plane dislocation density can be obtained, for example, by dividing the semiconductor part 8N to expose a side surface of the base B and performing CL measurement on the dislocation density on the side surface.

Regarding the wing F, the ratio (WF/d1) of a width WF (size in the first direction) to a thickness d1 can be set to 2.0 or more, for example. The WF/d1 can be 2.0 or more, 4.0 or more, 5.0 or more, 7.0 or more, or 10.0 or more. By setting WF/d1 to 2.0 or more, the internal stress of the semiconductor part 8N can be easily reduced. This makes it possible to reduce warpage of a wafer. The width WF of the wing F may be, for example, equal to or larger than 7.0 μm, equal to or larger than 10.0 μm, equal to or larger than 20.0 μm, or equal to or larger than 40.0 μm. The thickness d1 may be equal to or less than 10.0 μm, equal to or less than 5.0 μm, or equal to or less than 2.0 μm.

In the first example, the width Wm of the mask portion 5 was 50 μm, the width Wk of the opening portion K was 5 μm, the breadth of the semiconductor part 8N was 53 μm, the width (size in the X direction) of the wing F was 24 μm, and a layer thickness of the semiconductor part 8N was 5 μm. The aspect ratio of the semiconductor part 8N was 10.6 (=53 μm/5 μm), and thus a significantly high aspect ratio was achieved.

### Division of Semiconductor Part

In the first example, the plurality of trenches TR extending in the first direction (X direction) are formed in the semiconductor part 8N, thereby dividing the semiconductor part 8N into the plurality of base portions 8. The base portion 8 may be formed in an island shape (not connected to the surroundings) by the plurality of trenches TR and the gap GP. The etching to the semiconductor part 8N may be dry etching, and this dry etching may be stopped at the mask portion 5. In this case, the mask portion 5 functions as an etching stopper, and the mask portion 5 is exposed at the bottom of the trench TR. The etching does not necessarily need to stop at the surface of the mask portion 5 and may stop in the mask portion 5. The mask portion 5 is made of a material more difficult to be etched than the semiconductor part 8N, and a part of the mask portion 5 may be etched as long as the mask portion 5 plays a role of stopping etching.

When the trench TR is formed to extend in the width direction (X direction) of the opening portion K, a warpage of the wafer can be reduced. This effect is noticeable when a different substrate having a thermal expansion coefficient different from that of the semiconductor part 8N is used for the main substrate 1.

### Formation of Upper Layer Portion

In the first example, each upper layer portion 9 may be formed in an island shape corresponding to the base portion 8. The nitride semiconductor is hardly deposited on the mask portion 5 that is a selective growth mask, and since the upper layer portion 9 is grown on the upper surface and the side surface of the base portion 8 including the nitride semiconductor, the upper layer portion 9 can be formed in an island shape. In this manner, patterning damage can be avoided and the state of the light-emitting portion LP (see FIG. 11), which is an active layer of the upper layer portion 9, can be improved. The upper layer portion 9 may be formed in a portion overlapping the wing F in plan view above the base portion 8, or the base portion 8 may be exposed by digging a part of the upper layer portion 9 by etching or the like. For example, an n-type semiconductor layer 9A of the upper layer portion 9 may be exposed by digging a part of the upper layer portion 9 by etching or the like.

The upper layer portion 9 may be continuously formed using the same device (for example, an MOCVD device) as the device used to form the semiconductor part 8N, or after the semiconductor part 8N is formed, the substrate may be temporarily taken out of the device, the surface polishing of the semiconductor part 8N may be performed, and then the upper layer portion 9 may be formed. In addition to the MOCVD device, a sputtering device, a remote plasma chemical vapor deposition (RPCVD) device, a pulse sputter deposition (PSD) device, or the like can be used for forming the upper layer portion 9. Since the remote plasma CVD device and the PSD device do not use hydrogen as a carrier gas, a p-type GaN-based semiconductor part having a low resistance can be easily formed.

The MQW structure of the light-emitting portion LP in the upper layer portion 9 can be, for example, a structure of 2 to 6 periods of InGaN/GaN. The In composition may vary depending on intended emission wavelengths, and the In concentration can be set to be from about 15% to about 20% for blue light (near 450 nm) and to be about 30% for green light (near 530 nm). As needed, an electron-blocking layer (for example, an AlGaN layer) may be formed on the light-emitting portion LP. To reduce the resistance, a surface (about 10 nm) of the p-type semiconductor layer 9B may be a p-type highly doped layer.

The island-shaped portion including the base portion 8 and the upper layer portion 9 can be the second nitride semiconductor part NS2 in the light-emitting element 30 described above. The second nitride semiconductor part NS2 formed as described above includes the base portion 8 located below the light-emitting portion LP, and the base portion 8 includes the base B and a pair of wings F extending from the base B to both sides. In the second nitride semiconductor part NS2, the light-emitting portion LP and the wing F overlap each other in plan view. Since a portion of the upper layer portion 9 overlapping the wing F in plan view retains a low dislocation characteristic (low defect characteristic), the light emission efficiency in this portion can be increased.

### Separation of Element Portion

After the mask portion 5 is wet-etched to bring the base portion 8 of the second nitride semiconductor part NS2 into a state of being connected only to the underlying portion 4, the second nitride semiconductor part NS2 can be mechanically separated from the template substrate TS by using a temporary support member TM. The temporary support member TM may be an adhesive tape (for example, an adhesive dicing tape used when dicing a semiconductor wafer) or the like. A specific aspect of the temporary support member TM is not particularly limited.

A plurality of second nitride semiconductor parts NS2 adjacent to each other on the template substrate TS may be separated from each other by one temporary support member TM. A part of the plurality of second nitride semiconductor parts NS2 on the template substrate TS may be selectively separated from each other by using one temporary support member TM. For example, the plurality of second nitride semiconductor parts NS2 can be temporarily bonded to the temporary support member TM so as to straddle the plurality of second nitride semiconductor parts NS2, for example, every two or three second nitride semiconductor parts NS2.

Without being limited thereto, the second nitride semiconductor part NS2 may be bonded to the temporary support member TM by using solder, or may be peeled off using an adhesive stamp made of an adhesive material or a flexible material such as polydimethylsiloxane (PDMS) that is a silicone elastomer.

### Second Partial Step

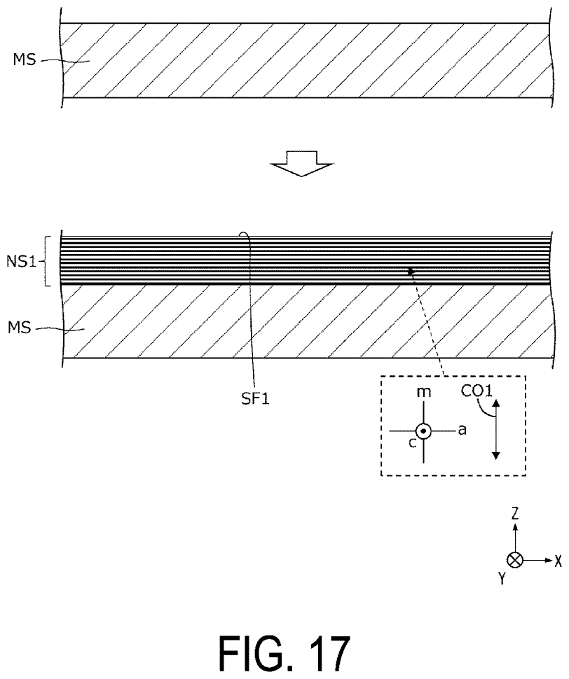

FIG. 17 is a step cross-sectional view illustrating an example of the second partial step in the manufacturing method of the light-emitting element in the first example. As illustrated in FIGS. 12 and 17, the second partial step S200 includes step S210 of preparing the main substrate MS and step S220 of forming the first nitride semiconductor part NS1.

The main substrate MS may be made of any one selected from the group consisting of silicon carbide (SiC), sapphire, and GaN. Without being limited thereto, in the first example, the main substrate MS may be made of any materials and have any plane orientations as long as the first nitride semiconductor part NS1 can be formed by m-plane growth. A SiC substrate may be adopted as the main substrate MS from the viewpoint of having an excellent thermal conductivity. The main substrate MS may be a light-shielding substrate (for example, a silicon substrate). A base substrate, in which the (11-22) plane of the GaN-based semiconductor layer is formed on a sapphire substrate, or a base substrate, in which the (20-21) plane of the GaN-based semiconductor layer is formed on a sapphire substrate, may be used as the main substrate MS. For example, a sapphire substrate having grooves formed therein can be used as the main substrate MS, and a GaN layer having a nonpolar plane (m-plane) can be formed on the main substrate MS. A sapphire substrate may be less expensive than a SiC substrate with a nonpolar surface.

The first nitride semiconductor part NS1 is formed on the main substrate MS. The first nitride semiconductor part NS1 may be formed on the main substrate MS via an underlying portion (for example, a GaN layer). As illustrated in FIG. 11, the epitaxial DBR having a high reflectance (for example, 96% or more) and a high thermal conductivity can be formed by layering 20 to 40 pairs of PFs, each pair PF including AlN in the first refractive portion R1 and GaN in the second refractive portion R2.

As described above, the first nitride semiconductor part NS1 has the first surface SF1 perpendicular to the first crystal orientation CO1 on the surface opposite to the main substrate MS. The specific configuration of the first nitride semiconductor part NS1 is not necessarily limited as long as the first nitride semiconductor part NS1 has birefringence with respect to light traveling in the direction of the first crystal orientation CO1. The first nitride semiconductor part NS1 can be, for example, an epitaxial DBR having a lattice matching system such as AlInN (first refractive portion R1)/GaN (second refractive portion R2).

The epitaxial DBR may be formed using an MOCVD method, or may be formed using an RPCVD method or a sputtering method (such as a PSD method) that enables low-temperature film formation. The low-temperature film formation method such as the RPCVD method or the PSD method can reduce the temperature difference between during and after the film formation, and suppress generation of cracks due to a difference in thermal expansion coefficient between the main substrate MS and the epitaxial DBR.

In the first example, 30 pairs of AIN (first refractive portion R1)/GaN (second refractive portion R2) were layered on a 4H-SiC substrate by an MOVPE method at a growing temperature of 1040° C. and a growing pressure of 50 Torr to form an epitaxial DBR. The design peak wavelength of the DBR was 400 nm, and the optical thickness of GaN in one pair was λ/4. Thus, the first nitride semiconductor part NS1 having a high light reflectance of about 99% can be obtained. The first nitride semiconductor part NS1 can function as a lower reflective layer of the VCSEL.

Unlike the example illustrated in FIG. 11, the uppermost portion of the first nitride semiconductor part NS1 may be the first refractive portion R1 (for example, ALN). The refractive material of the first refractive portion R1 may be AIN, AlInN, or InN. The second refractive portion R2 includes a GaN-based semiconductor (for example, GaN). The refractive material of the first refractive portion R1 may have a lattice constant different from that of the GaN-based semiconductor of the second refractive portion R2. The refractive material (for example, ALN) of the first refractive portion R1 may have a smaller lattice constant than the GaN-based semiconductor (for example, GaN) of the second refractive portion R2. The thermal expansion coefficient of the main material (for example, SiC, Si) of the main substrate MS<the thermal expansion coefficient of the GaN-based semiconductor (for example, GaN) of the second refractive portion R2<the thermal expansion coefficient of the refractive material (for example, ALN) of the first refractive portion R1.

### Third Partial Step

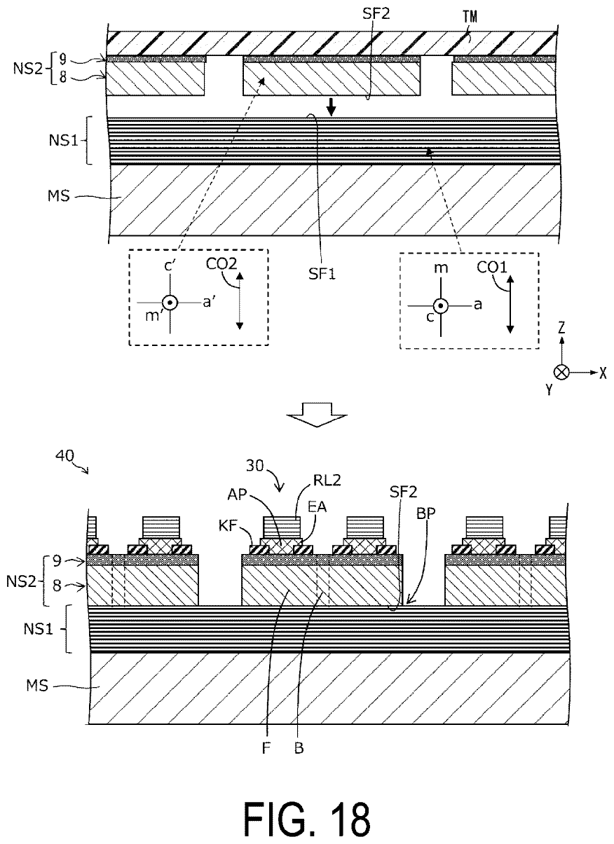

FIG. 18 is a step cross-sectional view illustrating an example of the third partial step in the manufacturing method of the light-emitting element in the first example. As illustrated in FIGS. 14 and 18, the third partial step S300 includes step S310 of bonding the first surface SF1 of the first nitride semiconductor part NS1 and the second surface SF2 of the second nitride semiconductor part NS2, step S320 of forming the insulating film (current constriction layer) KF, step S330 of forming the anode EA, the cathode EC, and the upper reflective layer RL2, and step S340 of singulating into the plurality of light-emitting elements 30.

### Bonding

First, a back surface of the base portion 8 in the second nitride semiconductor part NS2 temporarily supported by the temporary support member TM is planarized by polishing, chemical mechanical polish (CMP), or the like. The polishing may be, for example, lapping or buffing, and in this case, an abrasive may include, for example, colloidal silica, an oxidizing agent, or a mixture thereof. As the polishing technology, a polishing method known as a catalyst surface referred etching (CARE) method may be used. This makes it possible to set the RMS of the back surface of the base portion 8 corresponding to the second surface SF2 of the second nitride semiconductor part NS2 to, for example, 0.5 nm or less.

As described above, the base portion 8 is formed by the ELO method, and the back surface of the base portion 8 is a surface separated from the template substrate TS and thus has high flatness. By using the ELO method, the flatness of the back surface of the base portion 8 can be enhanced, and the separation from the template substrate TS can be easily performed. When the flatness of the back surface of the base portion 8 is sufficiently high, the above-described planarization process can be omitted.

The surface of the first nitride semiconductor part NS1 located on the main substrate MS may also be planarized by polishing, CMP, or the like as needed. This makes it possible to set the RMS of the surface (the first surface SF1) of the first nitride semiconductor part NS1 to, for example, 0.5 nm or less.

Subsequently, in the first example, the first surface SF1 of the first nitride semiconductor part NS1 and the second surface SF2 of the second nitride semiconductor part NS2 are bonded to each other in a crystal-orientation relationship in which the c-axis direction of the first nitride semiconductor part NS1 and the m′-axis direction of the second nitride semiconductor part NS2 are parallel to each other. Thus, the first nitride semiconductor part NS1, which is an m-plane DBR, and the second nitride semiconductor part NS2, which is a c-plane ELO layer, are bonded to each other. Subsequently, the second nitride semiconductor part NS2 and the temporary support member TM are separated from each other, and the plurality of second nitride semiconductor parts NS2 are transferred onto the first nitride semiconductor part NS1.

For example, the first surface SF1 and the second surface SF2 can be directly bonded by surface-activated bonding. Specifically, the first surface SF1 and the second surface SF2 are each plasma-treated in a vacuum. Thus, the surfaces can be cleaned and activated (dangling bonds are present on the surfaces). Subsequently, the first surface SF1 and the second surface SF2 are brought into contact with each other, so that the first nitride semiconductor part NS1 and the second nitride semiconductor part NS2 can be surface-activated bonded to each other. The direct bonding may be performed under heating or pressure. In the first example, the bonding portion BP may be an amorphous layer.

### Formation of Upper Structure

Subsequently, the insulating film KF is formed above the upper layer portion 9 to have the aperture portion AP (current constriction portion). The material of the insulating film KF is not particularly limited, but for example, SiOx, SiNx, AlOx, or the like can be used. In the first example, the insulating film KF was formed at two positions per second nitride semiconductor part NS2. Specifically, the insulating film KF was formed at one position above each of the two wings F of the base portion 8 (see FIG. 10).

The anode EA is formed to be in contact with the upper layer portion 9 in the aperture portion AP of the insulating film KF, and the cathode EC is formed on the base portion 8 (see FIGS. 9 and 10). The material of the cathode EC is not particularly limited. The anode EA and the cathode EC may be arranged in the Y direction (see FIG. 10).

The anode EA overlaps the wing F of the base portion 8 in plan view. The anode EA overlaps the light-emitting portion LP of the upper layer portion 9 in plan view. In the light-emitting element 30, light traveling back and forth between the first nitride semiconductor part NS1 and the upper reflective layer RL2 passes through the anode EA.

The anode EA is made of a transparent conductive material having light permeability. Examples of the transparent conductive material include indium tin oxide (including crystalline ITO, amorphous ITO, and Sn-doped In₂O₃), indium zinc oxide (IZO), F-doped In₂O₃ (IFO), tin oxide (including SnO₂, Sb-doped SnO₂, and F-doped SnO₂), and zinc oxide (including ZnO, Al-doped ZnO, and B-doped ZnO).

The anode EA may include at least one selected from the group consisting of gallium (Ga) oxide, titanium (Ti) oxide, niobium (Nb) oxide, and nickel (Ni) oxide. The aperture diameter of the anode EA (diameter of a current injection region in contact with a p-type semiconductor part) can be, for example, from 2 μm to 100 μm.

Subsequently, the upper reflective layer RL2 is formed above the anode EA. This can form the light-emitting substrate 40 having the plurality of light-emitting elements 30. The first example illustrates an example in which two light-emitting elements 30 are formed for each of the plurality of second nitride semiconductor parts NS2 disposed on the first nitride semiconductor part NS1.

In the first example, the upper reflective layer RL2 may be, for example, an amorphous dielectric. In the first example, the upper reflective layer RL2 may have a layered structure of crystalline layers of SiN or the like, for example, and in this case, the crystal orientation of each crystal is not particularly limited. As illustrated in FIG. 11, for example, the upper reflective layer RL2 may be a DBR in which the third refractive portion R3 and the fourth refractive portion R4 are alternately laminated. The third refractive portion R3 includes, for example, SiO₂ or the like. The fourth refractive portion R4 is a layer including a material having a higher index of refraction than the third refractive portion R3, and includes, for example, Ta₂O₅, HfO₂, ZrO₂, TiO₂, Al₂O₃, Nb₂O₅, ZnO, AlN, SiN, MgO, or the like. Light that is incident on an interface between the third refractive portion R3 and the fourth refractive portion R4 at an angle equal to or larger than a critical angle is totally reflected at the interface, thereby achieving a high light reflectance (for example, 96% or more) in the upper reflective layer RL2.

In the light-emitting element 30, the first nitride semiconductor part NS1 has a higher reflectance than the upper reflective layer RL2 with respect to the emission wavelength of the light-emitting portion LP. The first nitride semiconductor part NS1 may have a reflectance of approximately 100%, for example, approximately 99%. Thus, light traveling back and forth between the first nitride semiconductor part NS1 and the upper reflective layer RL2 is emitted as the laser beam LB mainly from the upper surface of the upper reflective layer RL2 (a portion overlapping the aperture portion AP in plan view).

Note that the light-emitting element 30 is not limited to a configuration in which the laser beam LB is emitted from the upper reflective layer RL2 side. The light-emitting element 30 may have a configuration in which the laser beam LB is emitted from the main substrate MS side (in other words, the first nitride semiconductor part NS1 side) when the main substrate MS does not have light transmissivity, or may have a configuration in which the laser beam LB is emitted from each of the main substrate MS side and the upper reflective layer RL2 side.

### Singulation

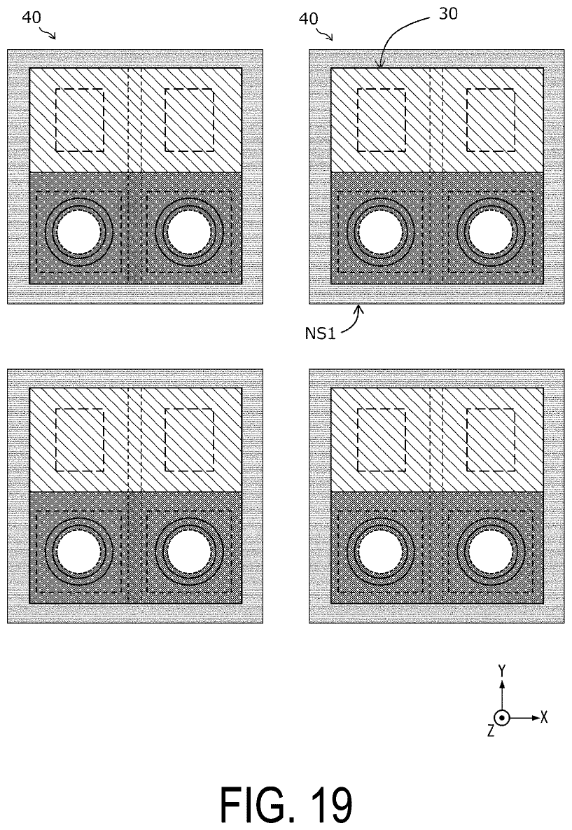

FIG. 19 is a plan view illustrating a singulated light-emitting substrate in the first example. As illustrated in FIG. 19, the light-emitting substrate 40 of FIG. 18 may be singulated into a plurality of light-emitting substrates 40 each including two light-emitting elements 30. In the first example, the light-emitting substrate 40 including four or more light-emitting elements 30 can be achieved.

### Other Configuration Examples

(a) In another configuration example of the first example, the template substrate TS used in the step of S100 may further have the following configuration. That is, in the template substrate TS, the seed region SA may be a region serving as a starting point of growth of the semiconductor part 8N; the template substrate TS may include the seed region SA and the growth suppression region DA above the main substrate 1. The template substrate TS may not include, for example, the mask portion 5. The template substrate TS may have an underlying layer located above the main substrate 1 and including an underlying material, and have a growth suppression region DA, in which the underlying material is modified, and a seed region SA, in which the underlying material is not modified, on the surface of the underlying layer. The underlying material may contain different materials (for example, a metal element other than a group III metal element) such as scandium (Sc), Zn, and Cr, and may be AlScN, ScN, ZnO, CrN, and the like. The underlying layer may have a single-layer structure or a multi-layer structure. The multi-layer structure may include a periodic structure. The semiconductor part 8N can be formed by the ELO method using such a template substrate TS.

(b) In another configuration example of the first example, in the step of S120 (see FIG. 12), a gap may be formed between the wing F and the mask portion 5 that is the growth suppression region DA. For example, the seed region SA may be located above the growth suppression region DA in the thickness direction of the template substrate TS. This makes it easy to improve the flatness of a back surface of the wing F.

(c) In another configuration example of the first example, in the step of S120 (see FIG. 12), the semiconductor parts 8N laterally grown in opposite directions from two adjacent opening portions K may be in contact (meet) with each other on the mask portion 5. In this case, by removing the met portion, a plurality of bar-shaped semiconductor parts 8N or island-shaped base portions 8 as illustrated in FIG. 14 may be formed.

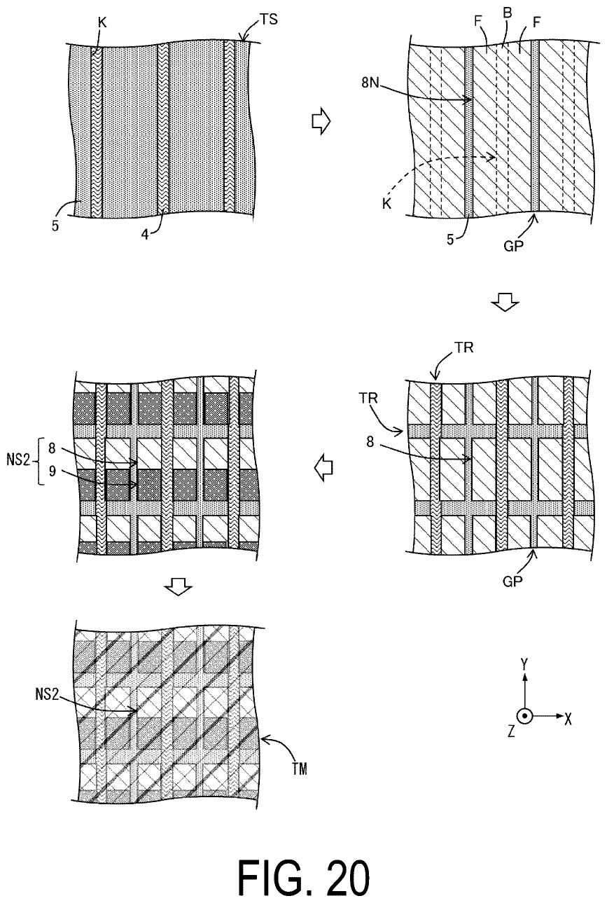

(d) FIG. 20 is a step plan view illustrating an example of the first partial step in the manufacturing method of the light-emitting element in another configuration example of the first example. As illustrated in FIG. 20, in another configuration example of the first example, trenches TR extending in the Y direction may be formed to remove the base B overlapping the opening portion K in plan view. The back surface of the wing F of the base portion 8 and the mask portion 5 are weakly bonded to each other by, for example, van der Waals force. In the step of S150 (see FIG. 12), the second nitride semiconductor part NS2 may be separated by the temporary support member TM without removing the mask portion 5. After the plurality of trenches TR are formed, an anchor film may be formed in contact with the side surface of the base portion 8 and the mask portion 5. The anchor film may be, for example, a dielectric film.

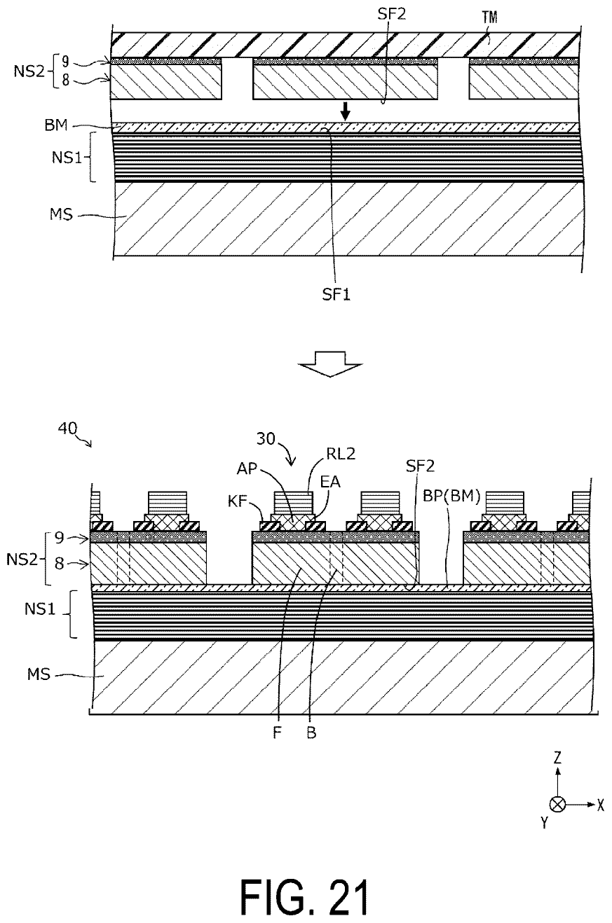

(e) FIG. 21 is a step cross-sectional view illustrating an example of the third partial step in the manufacturing method of the light-emitting element in another configuration example of the first example. As illustrated in FIG. 21, in the step of S310 (see FIG. 12), for example, a light-transmissive bonding material BM may be formed on the first nitride semiconductor part NS1, and the first surface SF1 and the second surface SF2 may be bonded to each other via the bonding material BM. In this case, the bonding portion BP may be a transparent adhesive layer (medium layer) formed of the bonding material BM. As the bonding material BM, for example, a transparent dielectric film can be used, and a specific example thereof includes silicon oxide (SiO₂). By setting the optical thickness of the transparent adhesive layer to λ/4, the bonding portion BP can be used as a part of the first nitride semiconductor part NS1.

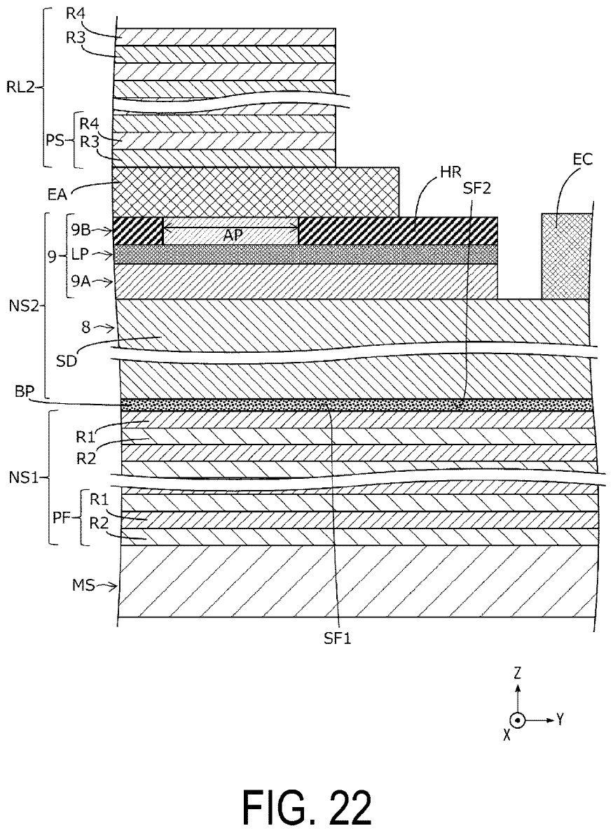

(f) FIG. 22 is a cross-sectional view illustrating another configuration example of the light-emitting element 30 in the first example. In the example illustrated in FIG. 11, the aperture portion AP is provided in the insulating film KF; however, the configuration is not limited thereto. As illustrated in FIG. 22, the configuration (in which an annular high-resistance portion HR surrounds the aperture portion AP) may be obtained by providing the high-resistance portion HR (region with a low p-type doping concentration) in the p-type semiconductor layer 9B and using an inner side of the high-resistance portion HR as the aperture portion AP (current constriction portion). The aperture portion AP can also be formed by implanting aluminum (Al) or iron (Fe) into the p-type semiconductor layer 9B. In order to obtain the effect of confining light due to a difference in the index of refraction in the aperture portion AP, the periphery of the aperture can be dug in to generate a difference in the index of refraction between the aperture portion AP and its periphery (for example, the index of refraction of the periphery is made smaller than that of the aperture portion AP).

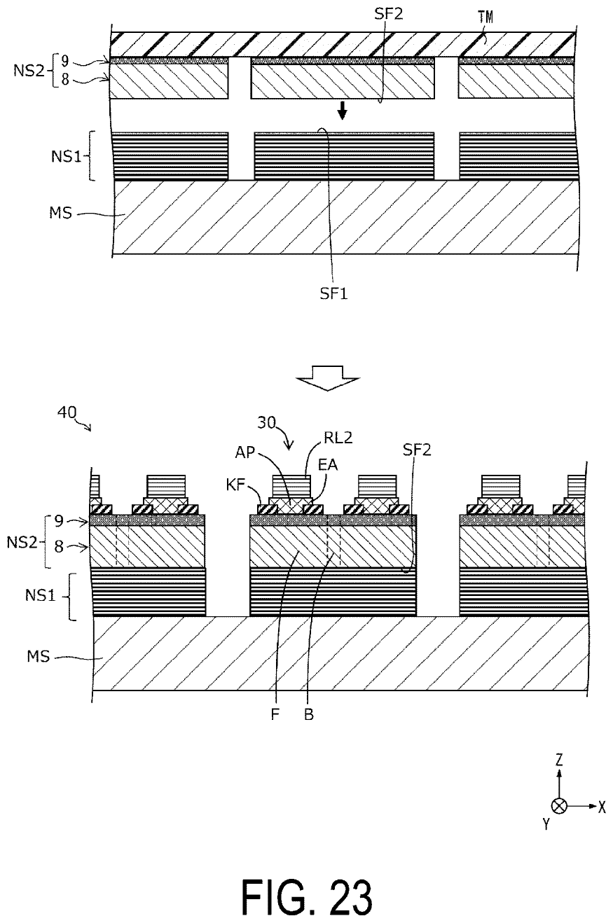

(g) FIG. 23 is a step cross-sectional view illustrating an example of the manufacturing method of the light-emitting element in another configuration example of the first example. In the example illustrated in FIG. 18 and the like, the first nitride semiconductor part NS1 is continuously formed on the surface of the main substrate MS; however, the configuration is not limited thereto. As illustrated in FIG. 23, the first nitride semiconductor part NS1 may be locally located on the main substrate MS to be two-dimensionally arranged in plan view.

(h) In the manufacturing method of the light-emitting element in another configuration example of the first example, in the first partial step S100 (see FIG. 12), the upper layer portion 9 may be formed on a plurality of bar-shaped semiconductor parts 8N without performing the step S130. A strip-shaped semiconductor part including the semiconductor part 8N and the upper layer portion 9 can be divided on the template substrate TS to form a plurality of second nitride semiconductor parts NS2. The strip-shaped semiconductor parts may be separated from the template substrate TS using, for example, the temporary support member TM, and then the strip-shaped semiconductor parts may be divided on the temporary support member TM to form a plurality of second nitride semiconductor parts NS2. The strip-shaped semiconductor parts may be divided by cleaving.

(i) As described above, the present disclosure relates to a novel finding of controlling the polarization direction of the laser beam LB emitted from the light-emitting element 30 in the c-plane direction of the light-emitting portion LP. Conventionally, for example, techniques of using asymmetric resonance or anisotropy of an optical gain have been proposed for control of the polarization direction, and the polarization direction of the laser beam LB can be more easily controlled by combining these techniques with the technology of the present disclosure. The effect of the birefringence characteristics (polarized light reflectance difference) of the first nitride semiconductor part NS1 or the upper reflective layer RL2 in the present disclosure can be enhanced by combining the above techniques.

For example, the light-emitting element 30 may have an asymmetric resonator shape by forming an asymmetric aperture, an asymmetric mesa, or the like so as to correspond to the birefringence characteristics (direction in which the polarized light reflectance is relatively high) of the first nitride semiconductor part NS1 or the upper reflective layer RL2. The light-emitting element 30 may be formed by bonding the second nitride semiconductor part NS2, which is formed by using a substrate having a high-index plane (for example, a c-plane off substrate or a nonpolar plane), to the first nitride semiconductor part NS1 so as to correspond to the birefringence characteristics of the first nitride semiconductor part NS1 or the upper reflective layer RL2. This makes it possible to more easily control the polarization direction of the laser beam LB.

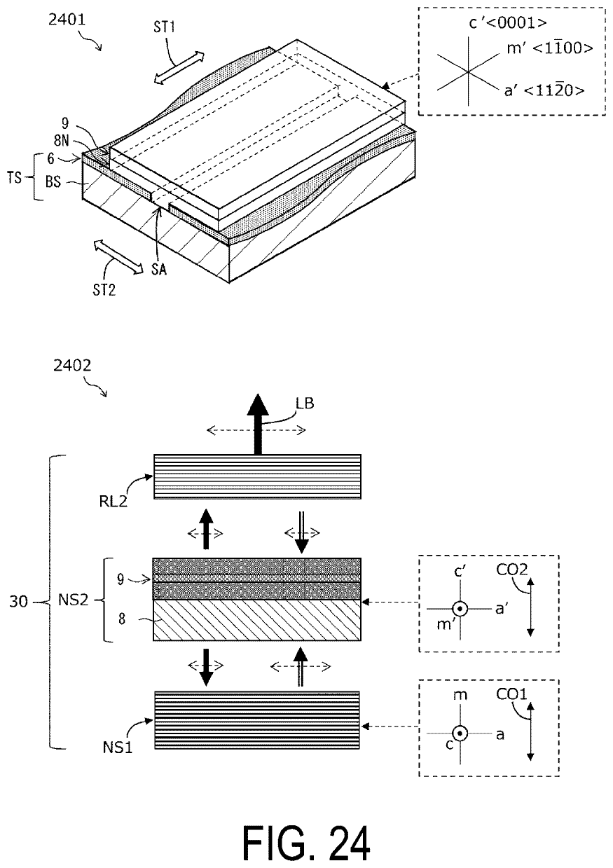

For example, the light-emitting portion LP of the light-emitting element 30 may have anisotropic strain. The anisotropic strain is described in detail below with reference to FIG. 24. FIG. 24 is a schematic view for explaining the light-emitting element in another configuration example of the first example.

In the light-emitting element 30, strain usually occurs in the light-emitting portion LP due to a difference in thermal expansion coefficient between the base portion 8 and the upper layer portion 9, a lattice mismatch, and the like. However, since such strain is isotropic in the c-plane and maintains the symmetry of the crystal, the strain does not particularly affect the polarization direction of light emitted from the light-emitting portion LP. On the other hand, when the crystal is formed in a stripe shape by, for example, the ELO method, a uniaxial stress may occur in the stripe direction, and in this case, an in-plane anisotropic strain may occur in the light-emitting portion LP formed by the c-plane growth. Specific examples are described below.

In one configuration example of the present disclosure, as illustrated in the drawing indicated by reference numeral 2401 in FIG. 24, the semiconductor part 8N is formed on the template substrate TS by the ELO method, and the upper layer portion 9 is formed on the semiconductor part 8N. The semiconductor part 8N is formed by lateral growth in the a′-axis direction with the m′-axis direction as the longitudinal direction, starting from the seed region SA exposed from the opening portion K in the mask pattern 6. The semiconductor part 8N may be divided into the base portions 8. When the base substrate BS in the template substrate TS is a different substrate, the following state may occur.

That is, for example, in a case in which the base substrate BS includes a silicon substrate, when the temperature of a semiconductor substrate having the semiconductor part 8N formed therein is lowered to room temperature under high-temperature conditions, the semiconductor part 8N and the base substrate BS shrink with the lowering of the temperature, but the degree of shrinkage of the semiconductor part 8N is larger than that of the base substrate BS. Therefore, in the semiconductor part 8N, tensile strain occurs in the longitudinal direction (stripe direction) and compressive strain occurs in the lateral direction. Since the light-emitting portion LP formed above the semiconductor part 8N generally includes a material having a larger lattice constant than the semiconductor part 8N, compressive strain occurs in the light-emitting portion LP. An underlying layer above the semiconductor part 8N, which serves as an underlayer for growing the light-emitting portion LP in the film formation process, has anisotropic strain, and when the light-emitting portion LP grows in a manner aligned with the underlying layer, compressive strain having different magnitudes in the longitudinal direction and the lateral direction occurs in the light-emitting portion LP (the magnitude of compressive strain in the longitudinal direction is smaller than that in the lateral direction). In this way, since anisotropic strain occurs in the light-emitting portion LP, light emitted from the light-emitting portion LP in the plane direction may have a specific polarization direction.

In the example illustrated in FIG. 24, the longitudinal direction of the semiconductor part 8N is the m′-axis direction, and in this case, the polarization direction of light emitted from the light-emitting portion LP is the a′-axis direction. It has been confirmed by experiments that light emitted from the light-emitting portion LP in a state where compressive strain has occurred has polarization characteristics in which the intensity in the a′-axis direction is larger than the intensity in the m′-axis direction. Whether the compressive strain or the tensile strain occurs in the light-emitting portion LP is determined corresponding to the relationship of the thermal expansion coefficients, the lattice constants, and the like of the respective materials of the base substrate BS, the semiconductor part 8N, and the upper layer portion 9. The in-plane anisotropic strain of the c-plane may cause the light-emitting portion LP to emit light having a specific polarization direction in the plane direction.

The diagram indicated by reference numeral 2402 in FIG. 24 schematically illustrates the first nitride semiconductor part NS1, the second nitride semiconductor part NS2, and the upper reflective layer RL2 in the light-emitting element 30. The second nitride semiconductor part NS2 is bonded to the first nitride semiconductor part NS1 so that the a-axis direction of the first nitride semiconductor part NS1 and the a′-axis direction of the second nitride semiconductor part NS2 are aligned with each other.

Light polarized in the a′-axis direction is emitted from the second nitride semiconductor part NS2 toward the first nitride semiconductor part NS1 and the upper reflective layer RL2. Since the first nitride semiconductor part NS1 has birefringence characteristics in which the polarized light reflectance in the a-axis direction is relatively higher than the polarized light reflectance in other directions, the polarization ratio of light reflected from the first surface SF1 may be higher than that of light incident on the first nitride semiconductor part NS1. In the light-emitting element 30, the first surface SF1 and the second surface SF2 may be bonded to each other in a manner that an angle formed by a specific polarization direction of light reflected from the first surface SF1 of the first nitride semiconductor part NS1 and the a′-axis direction of the second nitride semiconductor part NS2 is less than 5°. This makes it easier to increase the polarization ratio of the laser beam LB emitted from the light-emitting element 30 in a specific polarization direction.

Although FIG. 24 illustrates a single semiconductor part 8N and a single upper layer portion 9 extending in a stripe shape, a plurality of semiconductor parts 8N and a plurality of upper layer portions 9 can be formed on the template substrate TS as described above. A set of the semiconductor part 8N and the upper layer portion 9 is referred to as a strip-shaped semiconductor part. A semiconductor substrate in an aspect of the present disclosure includes the template substrate TS including the seed region SA and the growth suppression region DA, and a plurality of strip-shaped semiconductor parts located above the template substrate TS, the plurality of strip-shaped semiconductor parts being arranged in the first direction, each of the strip-shaped semiconductor parts including the light-emitting portion (light-emitting layer) LP including a c-plane nitride semiconductor, the light-emitting portion LP having anisotropic strain and emitting polarized light having a polarization direction in the first direction. The c-plane nitride semiconductor means a nitride semiconductor formed by c-plane film formation.

In this way, a light-emitting element that emits polarized light from each of the strip-shaped semiconductor parts can be obtained. The polarized light may be a laser beam. The first direction may be an a′-axis direction of the nitride semiconductor (for example, a GaN-based semiconductor). A plurality of light-emitting elements may be obtained by cleaving each of the strip-shaped semiconductor parts (for example, m-plane cleavage).

(j) In another configuration example of the first example, the first surface SF1 may be the a-plane or may be another nonpolar plane. For example, a (11-20) plane of GaN can be grown on an r-plane ((1-102) plane) of a sapphire substrate. Various GaN films having nonpolar planes can be formed using a sapphire substrate having grooves formed therein.

(k) In one configuration example of the present disclosure, the light-emitting element 30 may be an RCLED, and in this case, light emitted from the light-emitting element 30 in the plane direction has a specific polarization direction, and the polarization ratio thereof may be smaller than the polarization ratio of the specific polarization direction of the laser beam LB described above. The light emitted from the light-emitting element 30, which is an RCLED, may have a polarization ratio corresponding to the polarized light reflectance difference of the first nitride semiconductor part NS1 at the emission wavelength of light emitted from the light-emitting portion LP.

### Second Example

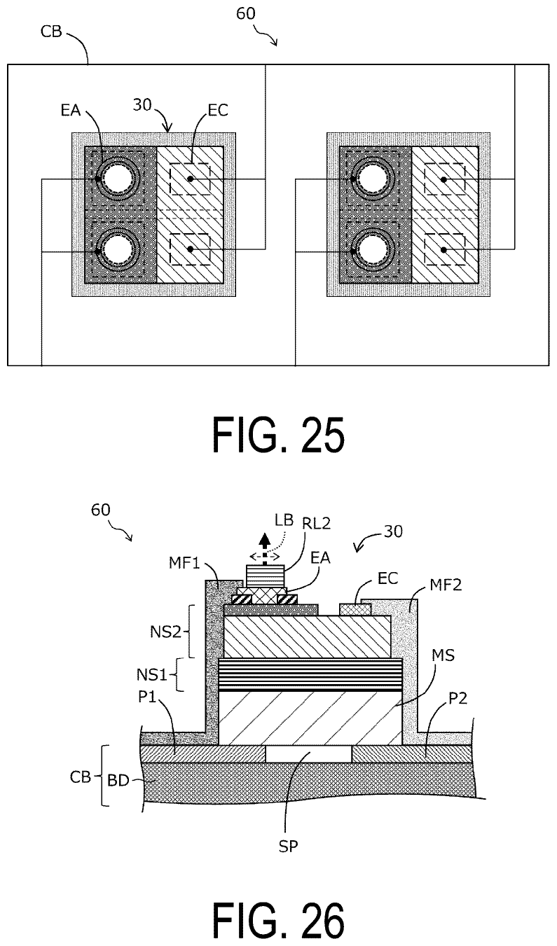

FIG. 25 is a plan view schematically illustrating a configuration of a laser element including a light-emitting element in a second example. FIG. 26 is a cross-sectional view schematically illustrating a configuration of the laser element including the light-emitting element in the second example.

As illustrated in FIGS. 25 and 26, a laser element 60 in the second example includes the light-emitting element 30 illustrated in FIGS. 8 to 10. In an example, the laser element 60 is obtained by mounting a plurality of light-emitting elements 30 on a circuit board CB. The laser element 60 emits a laser beam LB in the thickness direction of the second nitride semiconductor part NS2. In the laser element 60, the laser beam LB has a specific polarization direction. The specific polarization direction is, for example, the a-axis direction in the first nitride semiconductor part NS1. In the laser element 60, as described above, the first nitride semiconductor part NS1 has birefringence characteristics with respect to light having a specific emission wavelength from the light-emitting portion LP of the second nitride semiconductor part NS2. Thus, light having a specific wavelength and a specific polarization direction resonates in the laser element 60.

A specific method of mounting the light-emitting element 30 on the circuit board CB is not particularly limited, and a known technique can be used. In the example illustrated in FIG. 25, the circuit board CB may include a base portion BD, and a first pad portion P1 and a second pad portion P2 located above the base portion BD. A first electrically conductive film MF1 may be provided to electrically connect the first pad portion P1 and the anode EA to each other. A second electrically conductive film MF2 may be provided electrically connect the second pad portion P2 and the cathode EC to each other.

The laser element 60 may have a space SP between the light-emitting element 30 and the base portion BD.

A pad (first pad) in contact with the anode EA may be formed, and in this case, the first pad and the first electrically conductive film MF1 may be electrically connected. For example, the first pad may have a single-layer structure or a multi-layer structure including at least one selected from the group consisting of Au, Ag, Pd, Pt, Ni, Ti, V, W, Cr, Al, Cu, Zn, Sn, and In.

### Third Example

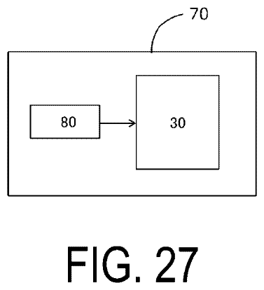

FIG. 27 is a schematic view illustrating a configuration of an electronic apparatus in a third example. An electronic apparatus 70 in FIG. 27 includes the light-emitting element 30 and a control unit 80 including a processor that controls the light-emitting element 30. Examples of the electronic apparatus 70 include a communication apparatus, an optical apparatus, a display apparatus, an illumination apparatus, a sensor apparatus, an information processing apparatus, a medical apparatus, and an electric vehicle (EV).

### Supplementary Notes

The invention according to the present disclosure has been described above based on various drawings and examples. However, the invention according to the present disclosure is not limited to the above-described embodiments and examples. That is, the invention according to the present disclosure can be variously changed within the scope illustrated in the present disclosure, and embodiments obtained by appropriately combining the technical means disclosed in different embodiments and examples are also included in the technical scope of the invention according to the present disclosure. In other words, a person skilled in the art can easily make various variations or corrections based on the present disclosure. Note that these variations or corrections are included within the scope of the present disclosure.

### Conclusion

A light-emitting element according to a first aspect of the present disclosure includes: a first nitride semiconductor part having a first surface perpendicular to a first crystal orientation; and a second nitride semiconductor part having a second surface perpendicular to a second crystal orientation different from the first crystal orientation and including a light-emitting layer located above the second surface, the second nitride semiconductor part being located above the first surface.

In the light-emitting element according to a second aspect of the present disclosure, in the first aspect, the first surface and the second surface are bonded to each other.

In the light-emitting element according to a third aspect of the present disclosure, in the first or second aspect, the first nitride semiconductor part has birefringence with respect to light traveling in the first crystal orientation.

In the light-emitting element according to a fourth aspect of the present disclosure, in any one of the first to third aspects, the second nitride semiconductor part has no birefringence with respect to light traveling in the second crystal orientation.

In the light-emitting element according to a fifth aspect of the present disclosure, in any one of the first to fourth aspects, light traveling from the first surface toward the second surface has a specific polarization direction with respect to the first crystal orientation.

In the light-emitting element according to a sixth aspect of the present disclosure, in any one of the first to fifth aspects, the light traveling from the first surface toward the second surface has a polarization ratio exceeding 50%.

In the light-emitting element according to a seventh aspect of the present disclosure, in any one of the first to sixth aspects, the first surface is a semipolar plane or a nonpolar plane.

In the light-emitting element according to an eighth aspect of the present disclosure, in any one of the first to seventh aspects, the first surface is an m-plane or an a-plane.

In the light-emitting element according to a ninth aspect of the present disclosure, in any one of the first to eighth aspects, light traveling from the first surface toward the second surface has a specific polarization direction with respect to the first crystal orientation, the first crystal orientation is an m-axis direction, and the specific polarization direction is an a-axis direction.

In the light-emitting element according to a tenth aspect of the present disclosure, in any one of the first to ninth aspects, light traveling from the first surface toward the second surface has a specific polarization direction with respect to the first crystal orientation, and the first surface and the second surface are bonded to each other in a manner that an angle formed by the specific polarization direction and an a-axis direction of the second nitride semiconductor part is less than 5°.

In the light-emitting element according to an eleventh aspect of the present disclosure, in any one of the first to tenth aspects, the second surface is a polar surface.

In the light-emitting element according to a twelfth aspect of the present disclosure, in any one of the first to eleventh aspects, the second surface is a-c-plane.

In the light-emitting element according to a thirteenth aspect of the present disclosure, in any one of the first to twelfth aspects, the light-emitting layer is a GaN-based semiconductor layer having a c-plane parallel to the second surface.

In the light-emitting element according to a fourteenth aspect of the present disclosure, in any one of the first to thirteenth aspects, the first nitride semiconductor part is a lower reflective layer.

The light-emitting element according to a fifteenth aspect of the present disclosure, further includes an upper reflective layer above the light-emitting layer in any one of the first to fourteenth aspects.

The light-emitting element according to a sixteenth aspect of the present disclosure further includes a main substrate made of any one selected from the group consisting of silicon carbide, sapphire, and GaN, and the first nitride semiconductor part is located on the main substrate, in any one of the first to fifteenth aspects.

In the light-emitting element according to a seventeenth aspect of the present disclosure, in any one of the first to sixteenth aspects, the first surface and the second surface are directly bonded to each other.

The light-emitting element according to an eighteenth aspect of the present disclosure further includes a transition layer between the first surface and the second surface in any one of the first to seventeenth aspects.

In the light-emitting element according to a nineteenth aspect of the present disclosure, in any one of the first to eighteenth aspects, the first surface and the second surface are bonded to each other via a light-transmissive bonding material.

In the light-emitting element according to a twentieth aspect of the present disclosure, in any one of the first to nineteenth aspects, each of the first nitride semiconductor part and the second nitride semiconductor part contains a GaN-based semiconductor.

In the light-emitting element according to a twenty-first aspect of the present disclosure, in any one of the first to twentieth aspects, the first nitride semiconductor layer is a lower reflective layer, and the lower reflective layer is a DBR having birefringence characteristics.

In the light-emitting element according to a twenty-second aspect of the present disclosure, in any one of the first to twenty-first aspects, the first nitride semiconductor layer is a lower reflective layer, and the lower reflective layer includes a plurality of nitride crystal layers having different indices of refraction.

In the light-emitting element according to a twenty-third aspect of the present disclosure, in any one of the first to twenty-second aspects, the second nitride semiconductor part includes a c-plane GaN-based semiconductor layer.

In the light-emitting element according to a twenty-fourth aspect of the present disclosure, in any one of the first to twenty-third aspects, each of the first surface and the second surface has an RMS of 0.5 nm or less.

In the light-emitting element according to a twenty-fifth aspect of the present disclosure, in any one of the first to twenty-fourth aspects, the first surface and the second surface are made of the same nitride semiconductor.

The light-emitting element according to a twenty-sixth aspect of the present disclosure, further includes an upper reflective layer above the light-emitting layer, in which the upper reflective layer is a DBR including a plurality of dielectric layers in any one of the first to twenty-fifth aspects.

In the light-emitting element according to a twenty-seventh aspect of the present disclosure, in any one of the first to twenty-sixth aspects, the second nitride semiconductor part includes a base portion located below the light-emitting layer, and the base portion includes a base and a pair of wings extending from the base to both sides.

In the light-emitting element according to a twenty-eighth aspect of the present disclosure, in the twenty-seventh aspect, the light-emitting layer and the wing overlap each other in plan view.

The light-emitting element according to a twenty-ninth aspect of the present disclosure further includes an anode, and the anode and the wing overlap each other in plan view, in the twenty-seventh or twenty-eighth aspect.

A laser element according to a thirtieth aspect of the present disclosure includes the light-emitting element according to any one of the first to twenty-ninth aspects.

In the laser element according to a thirty-first aspect of the present disclosure, in the thirtieth aspect, the laser element emits a laser beam in a thickness direction of the second nitride semiconductor part.

In the laser element according to a thirty-second aspect of the present disclosure, in the thirty-first aspect, the laser beam has a specific polarization direction.

In the laser element according to a thirty-third aspect of the present disclosure, in the thirty-second aspect, light having a specific wavelength and the specific polarization direction resonates.

An electronic apparatus according to a thirty-fourth aspect of the present disclosure includes the light-emitting element according to any one of the first to twenty-ninth aspects.

A semiconductor substrate according to a thirty-fifth aspect of the present disclosure includes: a template substrate including a seed region and a growth suppression region; and a plurality of strip-shaped semiconductor parts located above the template substrate, wherein the plurality of strip-shaped semiconductor parts are arranged in a first direction and each include a light-emitting layer containing a c-plane nitride semiconductor, and the light-emitting layer has anisotropic strain and emits polarized light having a polarization direction in the first direction.

A manufacturing method of a light-emitting element, according to a thirty-sixth aspect of the present disclosure includes: a step of forming a first nitride semiconductor part having a first surface perpendicular to a first crystal orientation; a step of forming a second nitride semiconductor part having a second surface perpendicular to a second crystal orientation different from the first crystal orientation and including a light-emitting layer located above the second surface; and a step of bonding the first surface and the second surface.

In the manufacturing method of a light-emitting element, according to a thirty-seventh aspect of the present disclosure, in the thirty-sixth aspect, the first nitride semiconductor part is crystal-grown on a main substrate, the second nitride semiconductor part crystal-grown on a template substrate including a seed region and a growth suppression region is peeled off, and the second surface of the peeled second nitride semiconductor part is bonded to the first surface of the first nitride semiconductor part.

In the manufacturing method of a light-emitting element, according to thirty-eighth aspect of the present disclosure, in the thirty-seventh aspect, the first surface and the second surface are bonded to each other by heating and/or pressurization.

The manufacturing method of a light-emitting element, according to a thirty-ninth aspect of the present disclosure, in the thirty-seventh aspect, the first surface and the second surface are bonded to each other via a light-transmissive bonding material.

A manufacturing device of a light-emitting element, according to a fortieth aspect of the present disclosure, performs the steps included in the manufacturing method of the light-emitting element according to any one of the thirty-sixth to thirty-ninth aspects.

### REFERENCE SIGNS

8 Base portion
9 Upper layer portion
30 Light-emitting element
BP Bonding portion
CO1 First crystal orientation
CO2 Second crystal orientation
EA Anode
EC Cathode
LB Laser beam
LP Light-emitting portion
NS1 First nitride semiconductor part
NS2 Second nitride semiconductor part
RL2 Upper reflective layer
SF1 First surface
SF2 Second surface

1. A light-emitting element comprising:
a first nitride semiconductor part having a first surface perpendicular to a first crystal orientation; and
a second nitride semiconductor part having a second surface perpendicular to a second crystal orientation different from the first crystal orientation and comprising a light-emitting layer located above the second surface, the second nitride semiconductor part being located above the first surface.

2. The light-emitting element according to claim 1, wherein the first surface and the second surface are bonded to each other.

3. The light-emitting element according to claim 1, wherein the first nitride semiconductor part has birefringence with respect to light traveling in the first crystal orientation.

4. The light-emitting element according to claim 1, wherein the second nitride semiconductor part has no birefringence with respect to light traveling in the second crystal orientation.

5. The light-emitting element according to claim 1, wherein light traveling from the first surface toward the second surface has a specific polarization direction with respect to the first crystal orientation.

6. The light-emitting element according to claim 1, wherein the light traveling from the first surface toward the second surface has a polarization ratio exceeding 50%.

7. The light-emitting element according to claim 1, wherein the first surface is a semipolar plane or a nonpolar plane.

8. The light-emitting element according to claim 1, wherein the first surface is an m-plane or an a-plane.

9. The light-emitting element according to claim 5,
wherein the first crystal orientation is an m-axis direction, and
the specific polarization direction is an a-axis direction.

10. The light-emitting element according to claim 5,
wherein the first surface and the second surface are bonded to each other in a manner that an angle formed by the specific polarization direction and an a-axis direction of the second nitride semiconductor part is less than 5°.

11. The light-emitting element according to claim 1, wherein the second surface is a polar surface.

12. The light-emitting element according to claim 1, wherein the second surface is a-c-plane.

13. The light-emitting element according toto claim 1, wherein the light-emitting layer is a GaN-based semiconductor layer having a c-plane parallel to the second surface.

14. The light-emitting element according to claim 1, wherein the first nitride semiconductor part is a lower reflective layer.

15. The light-emitting element according to claim 14, further comprising:
an upper reflective layer above the light-emitting layer.

16-17. (canceled)

18. The light-emitting element according to claim 1, further comprising:
a transition layer between the first surface and the second surface.

19. The light-emitting element according to claim 1, wherein the first surface and the second surface are bonded to each other via a light-transmissive bonding material.

20. The light-emitting element according to claim 1, wherein each of the first nitride semiconductor part and the second nitride semiconductor part contains a GaN-based semiconductor.

21-34. (canceled)

35. A semiconductor substrate comprising:
a template substrate comprising a seed region and a growth suppression region; and
a plurality of strip-shaped semiconductor parts located above the template substrate,
wherein the plurality of strip-shaped semiconductor parts are arranged in a first direction and each comprise a light-emitting layer containing a c-plane nitride semiconductor, and
the light-emitting layer has anisotropic strain and emits polarized light having a polarization direction in the first direction.

36. A manufacturing method of a light-emitting element, comprising the steps of:
forming a first nitride semiconductor part having a first surface perpendicular to a first crystal orientation;
forming a second nitride semiconductor part having a second surface perpendicular to a second crystal orientation different from the first crystal orientation and comprising a light-emitting layer located above the second surface; and
bonding the first surface and the second surface.

37-40. (canceled)
